(19) United States
(12) Patent Application Publication
(10) Pub. No.: US 2007/0158182 A1
(43) Pub. Date: Jul. 12, 2007

(54) Silicon dot forming method and apparatus

(75) Inventors: Eiji Takahashi, Kyoto-shi (JP); Atsushi Tomyo, Kyoto-shi (JP)

Correspondence Address: RADER FISHMAN & GRAUER PLLC, LION BUILDING, 1233 20TH STREET N.W., SUITE 501, WASHINGTON, DC, 20036, US

(73) Assignee: NISSIN ELECTRIC CO., LTD.

(21) Appl. No.: 11/524,450

(22) Filed: Sep. 21, 2006

(30) Foreign Application Priority Data
Sep. 26, 2005 (JP) 2005-277031

(51) Int. Cl. C08J 7/18; C23C 14/00; C23C 16/00

(52) U.S. Cl. 204/192.12; 427/553; 118/719; 204/298.25; 204/298.03

(57) ABSTRACT

A silicon sputter target is arranged in a silicon dot forming chamber, and a silicon dot formation target substrate is arranged in the chamber. Plasma is formed from a sputtering gas (typically a hydrogen gas) supplied into the chamber, and chemical sputtering is effected on the target with the plasma thus formed to form silicon dots on the substrate S. Optionally, with the plasma formed from a hydrogen gas and a silane-containing gas at a plasma emission intensity ratio (Si(288 nm)/Hβ) of 10.0 or lower, the silicon dots are formed on the substrate S. The silicon dots are terminally treated with the plasma derived from a terminally treating gas such as an oxygen gas.

### CROSS REFERENCE TO RELATED APPLICATION

This invention is based on Japanese Patent Application No. 2005-277031 filed in Japan on Sep. 26, 2005, the entire content of which is hereby incorporated by reference.

### BACKGROUND OF THE INVENTION

1. Field of the Invention

The present invention relates to a method and an apparatus for forming silicon dots (i.e., so-called silicon nanoparticles) of minute sizes that can be used as electronic device materials for single-electron devices and the like, and light emission materials and others.

2. Description of the Related Art

As a method of forming silicon nanoparticles, such a physical manner has been known that silicon is heated and vaporized in an inert gas by excimer laser or the like, and also an in-gas vaporizing method is known (see Kanagawa-ken Sangyo Gijutu Sougou Kenkyusho Research Report No. 9/2003, pp 77-78). The latter method is configured to heat and vaporize the silicon by high-frequency induction heating or arc discharge instead of laser.

Such a CVD method is further known that a material gas is supplied into a CVD chamber, and silicon nanoparticles are formed on a heated substrate (see JP 2004-179658 A).

In this method, nucleuses for growing silicon nanoparticles are formed on the substrate, and then the silicon nanoparticles are grown from the nucleuses.

Silicon dots are preferably those subjected to terminating treatment with oxygen, nitrogen or the like. The term “terminating treatment” refers to a treatment wherein, e.g. oxygen and/or nitrogen is bonded to the silicon dot to give a (Si—O) bond, a (Si—N) bond, a (Si—O—N) bond or the like.

The oxygen bond or nitrogen bond formed by such terminating treatment can function so as to compensate a defect, e.g., uncombined dangling bond, on the terminally untreated silicon dot and can give a state in which the defect is substantially suppressed as a whole.

When employed as electronic device materials, the silicon dots so terminally treated can achieve improvements in the properties required of the electronic devices. For example, when used as a light emission element material, the terminally treated silicon dots exhibit an enhanced luminance.

In connection with such terminating treatment, JP 2004-83299 A discloses a method for forming a silicon nanocrystal structure terminally treated with oxygen or nitrogen.

However, among conventional silicon dot forming methods, the method involving heating and vaporizing the silicon by laser irradiation can not uniformly control an energy density for irradiating the silicon with the laser, and therefore it is difficult to uniformize the particle diameters and density distribution of silicon dots. In the in-gas vaporizing method, the silicon is heated nonuniformly, and therefore the particle diameters and the density distribution of silicon dots are difficult to uniformize.

In the foregoing CVD method, the substrate must be heated to 550 deg. C. or higher for forming the nucleuses on the substrate, and the substrate of a low heat resistance can not be employed, which narrows a selection range of the substrate material.

The method for forming a silicon nanocrystal structure described in JP 2004-83299A involves the same problem as in formation of the conventional crystalline silicon thin film in that a silicon thin film of nanometer-scale thickness comprising silicon minute crystals and amorphous silicon is formed, prior to the terminating treatment, by a thermal catalysis reaction of a gas containing a hydrogenated silicon gas and a hydrogen gas or by applying a high-frequency electric field to a gas containing a hydrogenated silicon gas and a hydrogen gas to form plasma such that the subsequent step is executed with the plasma thus formed.

### SUMMARY OF THE INVENTION

An object of the invention is to provide a method in which silicon dots having substantially uniform particle diameters and exhibiting a substantially uniform density distribution are formed directly on a silicon dot formation target substrate at a low temperature as compared with the conventional CVD methods, and terminally treated silicon dots can be easily obtained from the silicon dots.

Also, it is an object of the invention to provide a silicon dot forming apparatus by which silicon dots having substantially uniform particle diameters and exhibiting a substantially uniform density distribution can be formed directly on a silicon dot formation target substrate at a low temperature as compared with the conventional CVD methods, and terminally treated silicon dots can be easily obtained from the silicon dots.

The inventors made a research for achieving the above objects, and found the followings.

Plasma is formed from a sputtering gas (e.g., a hydrogen gas), and chemical sputtering (reactive sputtering) is effected on a silicon sputter target with the plasma thus formed so that crystalline silicon dots having substantially uniform particle diameters and exhibiting a substantially uniform density distribution can be formed directly on the silicon dot formation target substrate at a low temperature.

For example, such plasma may be employed that a ratio (Si(288 nm)/Hβ) between an emission intensity Si(288 nm) of silicon atoms at a wavelength of 288 nm in plasma emission and an emission intensity Hβ of hydrogen atoms at a wavelength of 484 nm in the plasma emission is 10.0 or lower, more preferably 3.0 or lower, or 0.5 or lower, and chemical sputtering with this plasma can form crystalline silicon dots having substantially uniform particle diameters in a range not exceeding 20 nm or 10 nm and exhibiting a substantially uniform density distribution on the substrate even at a low temperature of 500 deg. C. or lower.

Such plasma formation can be performed by supplying the sputtering gas (e.g., hydrogen gas) into a plasma forming region and applying a high-frequency power to the gas.

Further, the plasma may be formed by applying a high-frequency power to a gas prepared by diluting a silane-containing gas with a hydrogen gas, and the plasma may be configured such that a ratio (Si(288 nm)/Hβ) between an emission intensity Si(288 nm) of silicon atoms at a wavelength of 288 nm in plasma emission and an emission intensity Hβ of hydrogen atoms at a wavelength of 484 nm in the plasma emission is 10.0 or lower, preferably 3.0 or lower, or 0.5 or lower. With this plasma, crystalline silicon dots can be directly formed on the silicon dot formation target substrate at a low temperature which have substantially uniform particle diameters and exhibit a substantially uniform density distribution.

For example, crystalline silicon dots having substantially uniform particle diameters in a range not exceeding 20 nm (and further 10 nm) and exhibiting a substantially uniform density distribution can be formed on the substrate at a low temperature of 500 deg. C. or lower.

Chemical sputtering may be effected on a silicon sputter target with a plasma derived from a hydrogen gas and a silane-containing gas in combination.

In any one of the above cases, the “substantially uniform particle diameters” of the silicon dots according to the invention represents the case where all the silicon dots have equal or substantially equal particle diameters as well as the case where the silicon dots have particle diameters which are not uniform to a certain extent, but can be practically deemed as the substantially uniform particle diameters.

For example, it may be deemed without any practical problem that the silicon dots have substantially uniform particle diameters when the particle diameters of the silicon dots fall or substantially fall within a predetermined range (e.g., not exceeding 20 nm, or not exceeding 10 nm). Also, even in the case where the particle diameters of the silicon dots are spread over a range from 5 nm to 6 nm and a range from 8 nm to 11 nm, it may be deemed without any practical problem that the particle diameters of the silicon dots substantially fall within a predetermined range (e.g., not exceeding 10 nm) as a whole. In these cases, the silicon dots have “substantially uniform particle diameters” according to the invention. In summary, the “substantially uniform particle diameters” of the silicon dots represents the particle diameters which are substantially uniform as a whole from a practical viewpoint.

Silicon dots terminally treated with oxygen or nitrogen can be easily obtained by exposing the silicon dots thus formed to a plasma produced from an oxygen-containing gas and/or nitrogen-containing gas.

[Silicon Dot Forming Method]

Based on the above findings, the invention provides the following roughly classified two types of silicon dot forming methods.

(1) First Type Silicon Dot Forming Method

A silicon dot forming method including:

a step of arranging a silicon sputter target in a silicon dot forming chamber;

a silicon dot forming step of arranging a silicon dot formation target substrate in the silicon dot forming chamber, supplying a sputtering gas into the chamber, applying a high-frequency power to the gas to generate plasma for sputtering in the camber, and forming silicon dots on the silicon dot formation target substrate by effecting chemical sputtering on the silicon sputter target with the plasma; and

a terminally treating step of arranging in a terminally treating chamber the substrate bearing the silicon dots formed thereon by the silicon dot forming step, supplying into the terminally treating chamber at least one terminally treating gas selected from an oxygen-containing gas and a nitrogen-containing gas, applying a high-frequency power to the gas(es) to generate plasma for terminating treatment, and terminally treating the silicon dots on the substrate with the terminally treating plasma thus formed.

(2) Second Silicon Dot Forming Method

A silicon dot forming method including:

a silicon dot forming step of supplying a silane-containing gas and a hydrogen-containing gas into a silicon dot forming chamber accommodating a silicon dot formation target substrate, applying a high-frequency power to the gases to generate plasma for silicon dot formation exhibiting a ratio (Si(288 nm)/Hβ) of 10.0 or lower between an emission intensity Si(288 nm) of silicon atoms at a wavelength of 288 nm in plasma emission and an emission intensity Hβ of hydrogen atoms at a wavelength of 484 nm in the plasma emission in the chamber, and thereby forming silicon dots on the substrate with the plasma thus formed; and

a terminally treating step of arranging in a terminally treating chamber the substrate bearing the silicon dots formed thereon by the silicon dot forming step, supplying into the terminally treating chamber at least one terminally treating gas selected from an oxygen-containing gas and a nitrogen-containing gas, applying a high-frequency power to the gas(es) to generate plasma for terminating treatment, and terminally treating the silicon dots on the substrate with the terminally treating plasma.

[Silicon Dot Forming Apparatus]

The invention provides the following first to fourth silicon dot forming apparatuses for implementing the silicon dot forming methods according to the invention.

(1) First Silicon Dot Forming Apparatus

A silicon dot forming apparatus including:

a silicon dot forming chamber having a holder for holding a silicon dot formation target substrate;

a hydrogen gas supply device supplying a hydrogen gas into the silicon dot forming chamber;

a silane-containing gas supply device supplying a silane-containing gas into the silicon dot forming chamber;

a first exhaust device exhausting a gas from the silicon dot forming chamber;

a first high-frequency power applying device applying a high-frequency power to the hydrogen gas supplied into the silicon dot forming chamber from the hydrogen gas supply device and the silane-containing gas supplied into the silicon dot forming chamber from the silane-containing gas supply device, and thereby forming plasma for forming a silicon film on an inner wall of the silicon dot forming chamber;

a second high-frequency power applying device applying a high-frequency power to the hydrogen gas supplied into the silicon dot forming chamber from the hydrogen gas supply device after the above silicon film formation, and thereby forming plasma for chemical sputtering on the silicon film as a sputter target;

an optical emission spectroscopic analyzer for plasma obtaining a ratio (Si(288 nm)/Hβ) between an emission intensity Si(288 nm) of silicon atoms at a wavelength of 288 nm and an emission intensity Hβ of hydrogen atoms at a wavelength of 484 nm in plasma emission in the silicon dot forming chamber;

a terminally treating chamber for terminating treatment of silicon dots which chamber has a holder holding a substrate having the silicon dots formed thereon;

a terminally treating gas supply device supplying at least one terminally treating gas selected from an oxygen-containing gas and a nitrogen-containing gas into the terminally treating chamber;

a second exhaust device exhausting a gas from the terminally treating chamber; and

a third high-frequency power applying device applying a high-frequency power to the terminally treating gas supplied into the terminally treating chamber from the terminally treating gas supply device, and thereby forming plasma for terminating treatment.

(2) Second Silicon Dot Forming Apparatus

A silicon dot forming apparatus including:

a target forming chamber having a holder for holding a sputter target substrate;

a first hydrogen gas supply device supplying a hydrogen gas into the target forming chamber;

a silane-containing gas supply device supplying a silane-containing gas into the target forming chamber;

a first exhaust device exhausting a gas from the target forming chamber;

a first high-frequency power applying device applying a high-frequency power to the hydrogen gas supplied into the target forming chamber from the first hydrogen gas supply device and the silane-containing gas supplied into the target forming chamber from the silane-containing gas supply device, and thereby forming plasma for forming a silicon film on the sputter target substrate to obtain a silicon sputter target;

a silicon dot forming chamber airtightly communicated with the target forming chamber and having a holder for holding a silicon dot formation target substrate;

a transferring device transferring the silicon sputter target from the target forming chamber to the silicon dot forming chamber without exposing the sputter target to an ambient air;

a second hydrogen gas supply device supplying a hydrogen gas into the silicon dot forming chamber;

a second exhaust device exhausting a gas from the silicon dot forming chamber;

a second high-frequency power applying device applying a high-frequency power to the hydrogen gas supplied from the second hydrogen gas supply device into the silicon dot forming chamber, and thereby forming plasma for effecting chemical sputtering on the silicon sputter target transferred from the target forming chamber;

an optical emission spectroscopic analyzer for plasma obtaining a ratio (Si(288 nm)/Hβ) between an emission intensity Si(288 nm) of silicon atoms at a wavelength of 288 nm and an emission intensity Hβ of hydrogen atoms at a wavelength of 484 nm in emission of the plasma for sputtering in the silicon dot forming chamber;

a terminally treating chamber for terminating treatment of silicon dots which chamber has a holder holding a substrate having the silicon dots formed thereon;

a terminally treating gas supply device supplying at least one terminally treating gas selected from an oxygen-containing gas and a nitrogen-containing gas into the terminally treating chamber;

a third exhaust device exhausting a gas from the terminally treating chamber; and

a third high-frequency power applying device applying a high-frequency power to the terminally treating gas supplied into the terminally treating chamber from the terminally treating gas supply device, and thereby forming plasma for terminating treatment.

(3) Third Silicon Dot Forming Apparatus

A silicon dot forming apparatus including:

a silicon dot forming chamber having a holder for holding a silicon dot formation target substrate;

a silicon sputter target disposed in the silicon dot forming chamber;

a hydrogen gas supply device supplying a hydrogen gas into the silicon dot forming chamber;

a first exhaust device exhausting a gas from the silicon dot forming chamber;

a first high-frequency power applying device applying a high-frequency power to the hydrogen gas supplied into the silicon dot forming chamber from the hydrogen gas supply device, and thereby forming plasma for chemical sputtering on the silicon sputter target;

an optical emission spectroscopic analyzer for plasma obtaining a ratio (Si(288 nm)/Hβ) between an emission intensity Si(288 nm) of silicon atoms at a wavelength of 288 nm and an emission intensity Hβ of hydrogen atoms at a wavelength of 484 nm in emission of the plasma for sputtering in the silicon dot forming chamber;

a terminally treating chamber for terminating treatment of silicon dots which chamber has a holder holding a substrate having the silicon dots formed thereon;

a terminally treating gas supply device supplying at least one terminally treating gas selected from an oxygen-containing gas and a nitrogen-containing gas into the terminally treating chamber;

a second exhaust device exhausting a gas from the terminally treating chamber; and

a second high-frequency power applying device applying a high-frequency power to the terminally treating gas supplied into the terminally treating chamber from the terminally treating gas supply device, and thereby forming plasma for terminating treatment.

(4) Fourth Silicon Dot Forming Apparatus

A silicon dot forming apparatus including:

a silicon dot forming chamber having a holder for holding a silicon dot formation target substrate;

a hydrogen gas supply device supplying a hydrogen gas into the silicon dot forming chamber;

a silane-containing gas supply device supplying a silane-containing gas into the silicon dot forming chamber;

a first exhaust device exhausting a gas from the silicon dot forming chamber;

a first high-frequency power applying device applying a high-frequency power to the gases supplied into the silicon dot forming chamber from the hydrogen gas supply device and the silane-containing gas supply device, and thereby forming plasma for silicon dot formation;

an optical emission spectroscopic analyzer for plasma obtaining a ratio (Si(288 nm)/Hβ) between an emission intensity Si(288 nm) of silicon atoms at a wavelength of 288 nm and an emission intensity Hβ of hydrogen atoms at a wavelength of 484 nm in emission of the plasma for silicon dot formation in the silicon dot forming chamber;

a terminally treating chamber for terminating treatment of silicon dots which chamber has a holder holding a substrate having the silicon dots formed thereon;

a terminally treating gas supply device supplying at least one terminally treating gas selected from an oxygen-containing gas and a nitrogen-containing gas into the terminally treating chamber;

a second exhaust device exhausting a gas from the terminally treating chamber; and

a second high-frequency power applying device applying a high-frequency power to the terminally treating gas supplied into the terminally treating chamber from the terminally treating gas supply device, and thereby forming plasma for terminating treatment.

The foregoing and other objects, features, aspects and advantages of the present invention will become more apparent from the following detailed description when taken in conjunction with accompanying drawings.

### BRIEF DESCRIPTION OF THE DRAWINGS

FIG. 1 shows a schematic structure of an example of the apparatus to be used in implementing the silicon dot forming method according to the invention.

FIG. 2 is a block diagram showing an example of an optical emission spectroscopic analyzer for plasma.

FIG. 3 is a block diagram showing a circuit example controlling an exhaust amount of an exhaust device (internal pressure of the silicon dot forming chamber).

FIG. 4 shows another example of the silicon dot forming apparatus.

FIG. 5 shows a positional relationship between a target substrate for forming a silicon film, electrodes and the like.

FIG. 6 shows an additional example of the silicon dot forming apparatus.

FIG. 7 schematically shows an example of a silicon dot structure obtained in an experimental example. according to the invention.

### DESCRIPTION OF THE PREFERRED EMBODIMENTS

### [1] Concerning the Silicon Dot Forming Method

Preferred embodiments of the silicon dot forming method according to the invention are roughly classified into the following two types.

<First Type Silicon Dot Forming Method>

A silicon dot forming method including:

a step of arranging a silicon sputter target in a silicon dot forming chamber; a silicon dot forming step of arranging a silicon dot formation target substrate in the silicon dot forming chamber, supplying a sputtering gas into the chamber, applying a high-frequency power to the gas to generate plasma for sputtering in the chamber, and forming silicon dots on the silicon dot formation target substrate by effecting chemical sputtering on the silicon sputter target with the plasma; and

a terminally treating step of arranging in a terminally treating chamber the substrate having the silicon dots formed thereon by the silicon dot forming step, supplying into the terminally treating chamber at least one terminally treating gas selected from an oxygen-containing gas and a nitrogen-containing gas, applying a high-frequency power to the gas(es) to generate plasma for terminating treatment, and terminally treating the silicon dots on the substrate with the terminally treating plasma thus formed.

(2) Second Type Silicon Dot Forming Method

A silicon dot forming method including:

a silicon dot forming step of supplying a silane-containing gas and a hydrogen gas into a silicon dot forming chamber accommodating a silicon dot formation target substrate, applying a high-frequency power to the gases to generate plasma for silicon dot formation, the plasma exhibiting a ratio (Si(288 nm)/Hβ) of 10.0 or lower between an emission intensity Si(288 nm) of silicon atoms at a wavelength of 288 nm in plasma emission and an emission intensity Hβ of hydrogen atoms at a wavelength of 484 nm in the plasma emission in the chamber, and thereby forming silicon dots on the substrate with the plasma thus formed; and

a terminally treating step of arranging in a terminally treating chamber the substrate bearing the silicon dots formed thereon by the silicon dot forming step, supplying into the terminally treating chamber at least one terminally treating gas selected from an oxygen-containing gas and a nitrogen-containing gas, applying a high-frequency power to the gas(es) to generate plasma for terminating treatment; and terminally treating the silicon dots on the substrate with the terminally treating plasma.

(1) Concerning the First Type Silicon Dot Forming Method

Three typical examples of the step of arranging a silicon sputter target in the silicon dot forming chamber in the first type silicon dot forming method are as follows.

(1-1) A Silicon Film is Formed on an Inner Wall of the Silicon Dot Forming Chamber and is Provided as the Silicon Sputter Target.

That is, a silane-containing gas and a hydrogen gas are supplied into the silicon dot forming chamber in the step of arranging a silicon sputter target in the silicon dot forming chamber. A high-frequency power is applied to the gases and thereby plasma for silicon film formation is generated so that a silicon film is formed on an inner wall of the chamber with the plasma to provide the silicon film as the silicon sputter target.

The “inner wall of the silicon dot forming chamber” may be the chamber wall itself, or an inner wall inside of the chamber wall or a combination thereof. The silicon dot forming method wherein a silicon sputter target is arranged in this manner may be mentioned as “first silicon dot forming method”.

(1-2) A Silicon Sputter Target Made in Another Chamber is Used.

In this case, the step of arranging a silicon sputter target in the silicon dot forming chamber includes a target forming step of arranging a target substrate in a target forming chamber, supplying a silane-containing gas and a hydrogen gas into the target forming chamber, applying a high-fluency power to the gases, forming plasma for silicon film formation in the chamber, forming a silicon film on the target substrate with the plasma thus formed to produce a silicon sputter target, and a step of transferring the silicon sputter target obtained in the target forming step from the target forming chamber to the silicon dot forming chamber without exposure of the silicon sputter target to an ambient air.

Hereinafter the silicon dot forming method wherein a silicon sputter target is provided in this manner may be called “second silicon dot forming method.

(1-3) The Silicon Sputter Target Already Formed is Used.

That is, a ready-made silicon sputter target is arranged in the silicon dot forming chamber independently in the step of arranging a silicon sputter target in the silicon dot forming chamber.

Hereinafter the silicon dot forming method wherein a silicon sputter target is provided in this manner may be called “third silicon dot forming method.”

(2) Concerning the Second Type Silicon Dot Forming Method

As in the second type silicon dot forming method, the method wherein a hydrogen gas and a silane-containing gas are used and wherein silicon dots are formed with the plasma derived from these gases may be called “fourth silicon dot forming method”.

(3) Concerning the First Type and Second Type Silicon Dot Forming Methods

According to the first silicon dot forming method, a silicon film serving as the silicon sputter target can be formed on the inner wall of the silicon dot forming chamber so that a silicon sputter target can be obtained with a larger area than when the ready-made (e.g., commercially available) silicon sputter target is laid independently in the silicon dot forming chamber. Thus, silicon dots can be uniformly formed over a wider area of the substrate.

According to the first and second silicon dot forming methods, silicon dots can be formed using a silicon sputter target kept from exposure to an ambient air. Therefore, the silicon dots can be formed wherein mixing of unintended material can be suppressed. In this way, crystalline silicon dots having substantially uniform particle diameters can be formed directly on the silicon dot formation target substrate in a uniform density distribution at a low temperature (e.g. with a substrate temperature of 500 deg. C. or lower).

In any one of the first, second and third silicon dot forming methods using the silicon sputter target, a hydrogen gas may be typically used as the gas for sputtering. The hydrogen gas may be employed as a mixture of the hydrogen gas and a rare-gas [at least one kind of gas selected from a group including helium gas (He), neon gas (Ne), argon gas (Ar), krypton gas (Kr) and xenon gas (Xe)].

That is to say, in any one of the first, second and third silicon dot forming methods, the hydrogen gas is supplied as a sputtering gas into the silicon dot forming chamber accommodating a silicon dot formation target substrate, and a high-frequency power is applied to the hydrogen gas to form plasma in the vacuum chamber in the silicon dot forming step. Then chemical sputtering is effected on the silicon sputter target with the plasma thus formed. Thereby crystalline silicon dots having a substantially uniform particle diameter and exhibiting a uniform density distribution can be formed directly on the silicon dot formation target substrate at a low temperature (e.g., with a substrate temperature of 500 deg. C. or lower).

For example, silicon dots having a particle diameter of 20 nm or less or 10 nm or less can be formed directly on said substrate at a low temperature of 500 deg. C. or lower (in other words, with a substrate temperature of, e.g., 500 deg. C. or lower).

In the first, second and third silicon dot forming methods, it is preferable that the plasma for chemical sputtering of the silicon sputter target in the silicon dot forming step exhibits a ratio (Si(288 nm)/Hβ) of 10.0 or lower, and more preferably 3.0 or lower between an emission intensity Si(288 nm) of silicon atoms at a wavelength of 288 nm in plasma emission and an emission intensity Hβ of hydrogen atoms at a wavelength of 484 nm in the plasma emission. The plasma may exhibit the ratio of 0.5 or lower.

It is also preferable that the silicon film forming plasma (plasma derived from a silane-containing gas and a hydrogen gas) for forming a silicon film as the silicon sputter target on the inner wall of the silicon dot forming chamber in the first silicon dot forming method, and the silicon film forming plasma (plasma derived from a silane-containing gas and a hydrogen gas) for forming a silicon film on the target substrate in the target forming chamber in the second silicon dot forming method exhibit a ratio (Si(288 nm)/Hβ) of 10.0 or lower, and more preferably 3.0 or lower between an emission intensity Si(288 nm) of silicon atoms at a wavelength of 288 nm in plasma emission and an emission intensity Hβ of hydrogen atoms at a wavelength of 484 nm in the plasma emission. The plasma may exhibit the ratio of 0.5 or lower.

The reason for this will be described later.

By the fourth silicon dot forming method, crystalline silicon dots having uniform particle diameters can be formed directly on the silicon dot formation target substrate in a uniform density distribution at a low temperature (e.g., with a substrate temperature of 500 deg. C. or lower).

For example, silicon dots having a particle diameter of 20 nm or less or 10 nm or less can be formed directly on the substrate at a low temperature of 500 deg. C. or lower (in other words, e.g., with a substrate temperature of 500 deg. C. or lower).

In the fourth silicon dot forming method, a silicon sputter target may be additionally disposed in the silicon dot forming chamber, and chemical sputtering of the target with plasma may be effected.

Such silicon sputter target can be provided as follows. As in the second silicon dot forming method, a target substrate is placed in the target forming chamber. Then a silane-containing gas and a hydrogen gas are supplied into the target forming chamber, and a high-fluency power is applied to the gases, thereby forming plasma for silicon film formation in the chamber. A silicon film is formed on the target substrate with the plasma thus formed, giving a silicon sputter target, and the step of transferring the silicon sputter target obtained in the target forming step from the target forming chamber to the silicon dot forming chamber is executed without exposure of the silicon sputter target to an ambient air, whereby the silicon sputter target is placed in the silicon dot forming chamber.

A ready-made silicon sputter target may be arranged in the silicon dot forming chamber independently.

In any one of the foregoing first to fourth silicon dot forming methods, when the emission intensity ratio (Si(288 nm)/Hβ) in the plasma is determined in a range of 10.0 or lower both in the silicon dot forming step and in the formation of silicon film as the silicon sputter target, this represents that the plasma is rich in hydrogen atom radicals.

In the first method, the plasma is formed from the silane-containing gas and the hydrogen gas for forming the silicon film serving as the sputter target on the inner wall of the silicon dot forming chamber. In the second method, the plasma is formed from the silane-containing gas and the hydrogen gas for forming the silicon film on the sputter target substrate. In each of these kinds of plasma formation, when the plasma exhibits the emission intensity ratio (Si(288 nm)/Hβ) of 10.0 or lower, and more preferably 3.0 or lower, or 0.5 or lower, a silicon film (silicon sputter target) of good quality suitable for forming the silicon dots on the silicon dot formation target substrate is smoothly formed on the inner wall of the chamber or the sputter target substrate at a low temperature of 500 deg. C. or lower.

In any one of the first, second and third silicon dot forming methods, when the plasma for sputtering the silicon sputter target in the silicon dot forming step exhibits an emission intensity ratio (Si(288 nm)/Hβ) of 10.0 or lower, and more preferably 3.0 or lower, or 0.5 or lower, it is possible to form the crystalline silicon dots having substantially uniform particle diameters in a range not exceeding 20 nm (and further 10 nm) and exhibiting a substantially uniform density distribution on the substrate at a low temperature of 500 deg. C. or lower.

In the fourth silicon dot forming method, when the plasma produced from the silane-containing gas and the hydrogen gas likewise exhibits the emission intensity ratio (Si(288 nm)/Hβ) of 10.0 or lower, and more preferably 3.0 or lower, or 0.5 or lower, it is possible to form the crystalline silicon dots having substantially uniform particle diameters in a range not exceeding 20 nm (and further 10 nm) and exhibiting a substantially uniform density distribution on the substrate at a low temperature of 500 deg. C. or lower.

In any one of the silicon dot forming methods, if the emission intensity ratio in the silicon dot forming step exceeds 10.0, it becomes difficult to grow crystal particles (dots), and a large amount of amorphous silicon is formed on the substrate. Therefore, the emission intensity ratio of 10.0 or lower is preferable. For forming the silicon dots of small particle diameters, the emission intensity ratio is more preferably 3.0 or lower, and may be 0.5 or lower.

However, if the emission intensity ratio takes an excessively small value, the growth of the crystal particles (dots) becomes slow, and it takes a long time to attain the required dot particle diameter. If the ratio takes a further small value, an etching effect exceeds the dot growth so that the crystal particles can not grow. The emission intensity ratio (Si(288 nm)/Hβ) may be substantially 0.1 or more although the value may be affected by various conditions and the like.

In forming the silicon film for obtaining the silicon sputter target, when the emission intensity ratio (Si(288 nm)/Hβ) in the plasma for forming the silicon film is controlled, the ratio may be substantially 0.1 or more although the value may be affected by various conditions and the like.

The value of emission intensity ratio (Si(288 nm)/Hβ) can be obtained, for example, based on a measurement result obtained by measuring the emission spectrums of various radicals with an optical emission spectroscopic analyzer for plasma.

The control of emission intensity ratio (Si(288 nm)/Hβ) can be performed by controlling the high-frequency power (e.g., frequency and/or magnitude of the power) applied to the supplied gas(es), gas pressure in the chamber during silicon dot formation (or silicon film formation), an amount of the gas (e.g., hydrogen gas, or hydrogen gas and silane-containing gas) supplied into the chamber, and the like.

According to the first, second and third silicon dot forming methods (and particularly in the case of using the hydrogen gas as the sputtering gas), when the chemical sputtering is effected on the silicon sputter target with the plasma exhibiting the emission intensity ratio (Si(288 nm)/Hβ) of 10.0 or lower, preferably 3.0 or lower, or 0.5 or lower, formation of the crystal nucleuses on the substrate is promoted, and the silicon dots grow from the nucleuses.

According to the fourth silicon dot forming method, the silane-containing gas and the hydrogen gas are excited and decomposed to promote the chemical reaction and therefore the formation of the crystal nucleuses on the substrate so that the silicon dots grow from the nucleuses. In the fourth method, the chemical sputtering of the silicon sputter target with the plasma may be additionally employed, which also promotes the formation of the crystal nucleuses on the substrate.

Since the crystal nucleus formation is promoted to grow the silicon dots, the nucleuses for growing the silicon dots can be formed relatively readily at a high density even when dangling bonds or steps that can form the nucleuses are not present on the silicon dot formation target substrate.

In a portion where the hydrogen radicals and hydrogen ions are richer than the silicon radicals and silicon ions, and the nucleuses are contained at an excessively large density, desorption of silicon is promoted by a chemical reaction between the excited hydrogen atoms or hydrogen molecules and the silicon atoms, and thereby the nucleus density of the silicon dots on the substrate becomes high and uniform.

The silicon atoms and silicon radicals obtained by decomposition with the plasma and excited by the plasma are absorbed to the nucleuses and grow to the silicon dots by chemical reaction. During this growth, the chemical reaction of absorption and desorption is promoted owing to the fact that the hydrogen radicals are rich, and the nucleuses grow to the silicon dots having substantially uniform crystal orientations and substantially uniform particle diameters. Owing to the above, the silicon dots having substantially uniform crystal orientations and particle sizes are formed on the substrate at a high density to exhibit a uniform distribution.

The invention is intended to form terminally treated silicon dots of minute particle diameters, e.g., of 20 nm or lower, and more preferably 10 nm or lower on the silicon dot formation target substrate. In practice, it is difficult to form silicon dots having extremely small particle diameters, and therefore the particle diameters are about 1 nm or more although this value is not restrictive. For example, the diameters may be substantially in a range of 3 nm to 15 nm, and more preferably in a range from 3 nm to 10 nm.

In the silicon dot forming steps of the silicon dot forming methods as described above, the silicon dots can be formed on the substrate at a low temperature of 500 deg. C. or lower (i.e., with the substrate temperature of 500 deg. C. or lower) and, in certain conditions, at a low temperature of 400 deg. C. or lower (i.e., with the substrate temperature of 400 deg. C. or lower). This increases a selection range of the substrate material. For example, the silicon dots can be formed on an inexpensive glass substrate having a low melting point and a heat-resistant temperature of 500 deg. C. or lower.

The invention is intended to form the silicon dots at a low temperature (typically, 500 deg. C. or lower). If the temperature of the silicon dot formation target substrate is too low, crystallization of the silicon becomes difficult. Therefore it is desired to form the silicon dots at a temperature of substantially 100 deg. C. or higher or 150 deg. C. or higher or 200 deg. C. or higher (in other words, a substrate temperature of 100 deg. C., or higher or 150 deg. C. or higher,

or 200 deg. C. or higher), although this depends on other various conditions (e.g., heat resistance of substrate as one of them).

As in the fourth silicon dot forming method already described, when both the silane-containing gas and the hydrogen gas are used as gases for generating the plasma for silicon dot formation, a gas supply flow rate ratio (silane-containing gas flow rate)/(hydrogen gas flow rate) into the vacuum chamber may be in a range from 1/200 to 1/30.

If the ratio is smaller than 1/200, the crystal particles (dots) grow slowly, and a long time is required for achieving a required dot particle diameter. If the ratio is further smaller, the crystal particles (dots) can not grow. If the ratio is larger than 1/30, it becomes difficult to grow the crystal particles (dots), and a large amount of amorphous silicon is formed on the substrate.

When the supply flow rate of the silane-containing gas is, e.g., in a range from 1 sccm to 5 sccm, it is preferable that (silane-containing gas supply amount (sccm))/(vacuum chamber capacity (liter)) is in a range from 1/200 to 1/30.

If this ratio is smaller than 1/200, the crystal particles (dots) grow slowly, and a long time is required for achieving a required dot particle diameter. If the ratio is further smaller than the above, the crystal particles (dots) can not grow. If the ratio is larger than 1/30, it becomes difficult to grow the crystal particles (dots), and a large amount of amorphous silicon is formed on the substrate.

In any one of the first to fourth silicon dot forming methods, the pressure in the silicon dot forming chamber during the silicon dot formation (in other words, during formation of plasma for silicon dot formation) may be in a range from about 0.1 Pa to about 10.0 Pa.

If the pressure is lower than 0.1 Pa, the crystal particles (dots) grow slowly, and a long time is required for achieving a required dot particle diameter. If the pressure is smaller than the above, the crystal particles (dots) can not grow. If the pressure is higher than 10.0 Pa, it becomes difficult to grow the crystal particles (dots), and a large amount of amorphous silicon is formed on the substrate.

When the silicon sputter target obtained outside the silicon dot forming chamber is employed as in the second or third silicon dot forming method as well as in the case of employing, in a combined manner, the chemical sputtering of the silicon sputter target in the fourth silicon dot forming method, the silicon sputter target may be primarily made of silicon, and may be made of, e.g. single-crystalline silicon, polycrystalline silicon, microcrystalline silicon, amorphous silicon or a combination of two or more of them.

The silicon sputter target may be appropriately selected depending on uses of the silicon dots from a group including a target not containing impurities, a target containing a very small amount of impurities and a target containing an appropriate amount of impurities exhibiting a predetermined resistivity.

For example, the silicon sputter target free of impurities and the silicon sputter target containing a very small amount of impurities may be a silicon sputter target in which an amount of each of phosphorus (P), boron (B) and germanium (Ge) is lower than 10 ppm.

The silicon sputter target exhibiting a predetermined resistivity may be a silicon sputter target exhibiting the resistivity from 0.001 ohm·cm to 50 ohm·cm.

In the second and third silicon dot forming methods as well as in the case of employing, in a combined manner, the chemical sputtering of the silicon sputter target in the fourth silicon dot forming method, when the silicon sputter target is independently arranged or located in the silicon dot forming chamber, the arrangement of the target in the silicon dot forming chamber is merely required to locate the target in the position allowing the chemical sputtering with the plasma, and the target may be arranged, e.g., along the whole or a part of the inner wall of the silicon dot forming chamber. It may be independent in the chamber. The arrangement along the inner wall of the chamber and the independent arrangement may be employed in combination.

In the case where the silicon film is formed on the inner wall of the silicon dot forming chamber (the chamber wall itself, an internal wall along the inside of the chamber wall or a combination thereof) to provide the silicon sputter target, or the silicon sputter target is arranged along the inner wall of the chamber, the chamber can be heated to heat the silicon sputter target, and the heated target can be sputtered more readily than the sputter target at room temperature, and thus can readily form the silicon dots at a high density.

For example, the silicon dot forming chamber may be heated to 80 deg. C. or higher, e.g., by a band heater, heating jacket or the like. In view of economical reason or the like, the upper limit of the heating temperature is, e.g., about 300 deg. C. If O-rings or the like are used in the chamber, the temperature must be lower than 300 deg. C. in some cases depending on heat resistance thereof.

In any one of the silicon dot forming methods, the high-frequency power is applied to the gas supplied into the silicon dot forming chamber in the silicon dot forming step, or the gas supplied into the target forming chamber in employing the target forming chamber, or the gas supplied into the terminally treating chamber in the terminally treating step, using an electrode which may be of either an inductive coupling type or a capacitive coupling type. When the employed electrode is of the inductive coupling type, it may be arranged in the chamber or outside the chamber.

The electrode arranged in the chamber may be coated with an electrically insulating film containing e.g., silicon or aluminum (e.g., silicon film, silicon nitride film, silicon oxide film or alumina film) for maintaining high-density plasma, and suppressing mixing of impurities into the silicon dots due to sputtering of the electrode surface and the like.

When the capacitive coupling type electrode is employed in the silicon dot forming chamber, it is recommended to arrange the electrode perpendicularly to the substrate surface (more specifically, perpendicularly to a surface including the silicon dot formation target substrate surface) so that it may not impede the silicon dot formation on the substrate.

In any one of the above cases, the frequency of the high-frequency power for the plasma formation may be in a range from about 13 MHz to about 100 MHz in view of relatively inexpensive processing. If the frequency is higher than 100 MHz, the electric power cost becomes high, and matching becomes difficult when the high-frequency power is applied.

In any one of the above cases, a power density (applied power (W: watt))/(silicon dot forming chamber capacity (L: liter)) is preferably in a range from about 5 W/L to about 100 W/L. If it is lower than 5 W/L, such a situation occurs to a higher extent that the silicon on the substrate becomes amorphous silicon, and is unlikely to form crystalline dots. If the density is larger than 100 W/L, a large damage is caused to the silicon dot formation target substrate surface (e.g., a silicon oxide film formed over a silicon wafer and defining the surface of the substrate). The upper limit may be about 50 W/L.

In any one of the silicon dot forming methods, the terminally treating chamber used in the terminally treating step may be structured to serve as both the silicon dot forming chamber and the terminally treating chamber. The terminally treating chamber may be arranged independently of the silicon dot forming chamber.

The terminally treating chamber communicated with the silicon dot forming chamber may be used. When the terminally treating chamber is employed to serve as the silicon dot forming chamber or when the terminally treating chamber is communicated with the silicon dot forming chamber, the silicon dots can be inhibited from contamination prior to terminating treatment.

When the terminally treating chamber is communicated with the silicon dot forming chamber, the two chambers may be communicated with each other either directly or via a substrate transferring chamber having a substrate transferring device.

In either case, a high-frequency discharge electrode for applying the high-frequency power to the terminally treating gas may be an electrode intended to generate a capacitively coupled plasma or an inductively coupled plasma.

The terminally treating gas may be, for example, an oxygen-containing gas and/or a nitrogen-containing gas as described above. The oxygen-containing gas is inclusive of an oxygen gas and nitrogen oxide (N₂O) gas, and the nitrogen-containing gas is inclusive of a nitrogen gas and ammonia (NH₃) gas.

### [2] Silicon Dot Structure

The invention also includes a silicon dot structure including the silicon dots that are formed by any one of the silicon dot forming methods already described.

### [3] Silicon dot forming apparatus

The invention provides the following first to fourth silicon dot forming apparatuses as preferred embodiments of the invention.

(1) First Silicon Dot Forming Apparatus

A silicon dot forming apparatus including:

a silicon dot forming chamber having a holder for holding a silicon dot formation target substrate;

a hydrogen gas supply device supplying a hydrogen gas into the silicon dot forming chamber;

a silane-containing gas supply device supplying a silane-containing gas into the silicon dot forming chamber;

a first exhaust device exhausting a gas from the silicon dot forming chamber;

a first high-frequency power applying device applying a high-frequency power to the hydrogen gas supplied into the silicon dot forming chamber from the hydrogen gas supply device and the silane-containing gas supplied into the silicon dot forming chamber from the silane-containing gas supply device, and thereby forming plasma for forming a silicon film on an inner wall of the silicon dot forming chamber;

a second high-frequency power applying device applying a high-frequency power to the hydrogen gas supplied into the silicon dot forming chamber from the hydrogen gas supply device after the above silicon film formation, and thereby forming plasma for chemical sputtering on the silicon film serving as a sputter target;

an optical emission spectroscopic analyzer for plasma obtaining a ratio (Si(288 nm)/Hβ) between an emission intensity Si(288 nm) of silicon atoms at a wavelength of 288 nm and an emission intensity Hβ of hydrogen atoms at a wavelength of 484 nm in plasma emission in the silicon dot forming chamber;

a terminally treating chamber for terminating treatment of silicon dots which chamber has a holder holding a substrate having the silicon dots formed thereon;

a terminally treating gas supply device supplying at least one terminally treating gas selected from an oxygen-containing gas and a nitrogen-containing gas into the terminally treating chamber;

a second exhaust device exhausting a gas from the terminally treating chamber; and

a third high-frequency power applying device applying a high-frequency power to the terminally treating gas supplied into the terminally treating chamber from the terminally treating gas supply device and forming plasma for terminating treatment.

This first silicon dot forming apparatus can implement the first silicon dot forming method.

The first silicon dot forming apparatus may further include a control portion comparing the emission intensity ratio (Si(288 nm)/Hβ) obtained by the optical emission spectroscopic analyzer for plasma with a reference emission intensity ratio (Si(288 nm)/Hβ) predetermined within a range not exceeding 10.0 in the process of forming the plasma by at least the second high-frequency power applying device in a group including the first and second high-frequency power applying devices, and controlling at least one of a power output of the second high-frequency power applying device, a supply amount of the hydrogen gas supplied from the hydrogen gas supply device into the silicon dot forming chamber and an exhaust amount of the exhaust device such that the emission intensity ratio (Si(288 nm)/Hβ) of the plasma changes toward the reference emission intensity ratio.

In any one of the above cases, the first and second high-frequency power applying devices may partially or entirely share the same structure.

The reference emission intensity ratio may be determined in a range not exceeding 3.0 or 0.5.

(2) Second Silicon Dot Forming Apparatus

A silicon dot forming apparatus including:

a target forming chamber having a holder for holding a sputter target substrate;

a first hydrogen gas supply device supplying a hydrogen gas into the target forming chamber;

a silane-containing gas supply device supplying a silane-containing gas into the target forming chamber;

a first exhaust device exhausting a gas from the target forming chamber;

a first high-frequency power applying device applying a high-frequency power to the hydrogen gas supplied into the target forming chamber from the first hydrogen gas supply device and the silane-containing gas supplied into the target forming chamber from the silane-containing gas supply device, and thereby forming plasma for forming a silicon film on the sputter target substrate to obtain a silicon sputter target;

a silicon dot forming chamber airtightly communicated with the target forming chamber and having a holder for holding a silicon dot formation target substrate;

a transferring device transferring the silicon sputter target from the target forming chamber into the silicon dot forming chamber without exposing the silicon sputter target to an ambient air;

a second hydrogen gas supply device supplying a hydrogen gas into the silicon dot forming chamber;

a second exhaust device exhausting a gas from the silicon dot forming chamber;

a second high-frequency power applying device applying a high-frequency power to the hydrogen gas supplied from the second hydrogen gas supply device into the silicon dot forming chamber, and thereby forming plasma for effecting chemical sputtering on the silicon sputter target transferred from the target forming chamber;

an optical emission spectroscopic analyzer for plasma obtaining a ratio (Si(288 nm)/Hβ) between an emission intensity Si(288 nm) of silicon atoms at a wavelength of 288 nm and an emission intensity Hβ of hydrogen atoms at a wavelength of 484 nm in emission of the plasma for sputtering in the silicon dot forming chamber;

a terminally treating chamber for terminating treatment of silicon dots which chamber has a holder holding a substrate having the silicon dots formed thereon;

a terminally treating gas supply device supplying at least one terminally treating gas selected from an oxygen-containing gas and a nitrogen-containing gas into the terminally treating chamber;

a third exhaust device exhausting a gas from the terminally treating chamber; and

a third high-frequency power applying device applying a high-frequency power to the terminally treating gas supplied into the terminally treating chamber from the terminally treating gas supply device, and thereby forming plasma for terminating treatment.

This second silicon dot forming apparatus can implement the second silicon dot forming method.

The second silicon dot forming apparatus may further include a control portion comparing the emission intensity ratio (Si(288 nm)/Hβ) obtained by the optical emission spectroscopic analyzer for plasma with a reference emission intensity ratio (Si(288 nm)/Hβ) predetermined within a range not exceeding 10.0 in the process of forming the plasma for sputtering by the second high-frequency power applying device, and controlling at least one of a power output of the second high-frequency power applying device, a supply amount of the hydrogen gas supplied from the second hydrogen gas supply device into the silicon dot forming chamber and an exhaust amount of the second exhaust device such that the emission intensity ratio (Si(288 nm)/Hβ) of the plasma in the silicon dot forming chamber changes toward the reference emission intensity ratio.

In any one of the above cases, the apparatus may include, for the target forming chamber, an optical emission spectroscopic analyzer for plasma obtaining a ratio (Si(288 nm)/Hβ) between an emission intensity Si(288 nm) of silicon atoms at a wavelength of 288 nm and an emission intensity Hβ of hydrogen atoms at a wavelength of 484 nm in plasma emission in the target forming chamber. In this case, a control portion similar to the above may be employed for this analyzer.

The first, second and third high-frequency power applying devices may partially or entirely share the same structure.

The first and second hydrogen gas supply devices may partially or entirely share the same structure.

The first, second and third exhaust devices may partially or entirely share the same structure.

The transferring device may be arranged, e.g., in the silicon dot forming chamber or in the target forming chamber. The silicon dot forming chamber and the target forming chamber may be directly connected together via a gate valve or the like, or may be indirectly connected together via a substrate transferring chamber laid between them and provided with the foregoing transferring device.

In any one of the above cases, the reference emission intensity ratio may be determined in a range not exceeding 3.0 or 0.5.

The apparatus may be provided with a second silane-containing gas supply device supplying a silane-containing gas into the silicon dot forming chamber, whereby the apparatus can implement the method involving additionally employing the chemical sputtering of the silicon sputter target in the foregoing fourth silicon dot forming method.

(3) Third Silicon Dot Forming Apparatus

A silicon dot forming apparatus including:

a silicon dot forming chamber having a holder for holding a silicon dot formation target substrate;

a silicon sputter target arranged in the silicon dot forming chamber;

a hydrogen gas supply device supplying a hydrogen gas into the silicon dot forming chamber;

a first exhaust device exhausting a gas from the silicon dot forming chamber;

a first high-frequency power applying device applying a high-frequency power to the hydrogen gas supplied into the silicon do forming chamber from the hydrogen gas supply device and thereby forming plasma for chemical sputtering on the silicon sputter target;

an optical emission spectroscopic analyzer for plasma obtaining a ratio (Si(288 nm)/Hβ) between an emission intensity Si(288 nm) of silicon atoms at a wavelength of 288 nm and an emission intensity Hβ of hydrogen atoms at a wavelength of 484 nm in emission of the plasma for sputtering in the silicon dot forming chamber;

a terminally treating chamber for terminating treatment of silicon dots which chamber has a holder holding a substrate having the silicon dots formed thereon;

a terminally treating gas supply device supplying at least one terminally treating gas selected from an oxygen-containing gas and a nitrogen-containing gas into the terminally treating chamber;

a second exhaust device exhausting a gas from the terminally treating chamber; and

a second high-frequency power applying device applying a high-frequency power to the terminally treating gas supplied into the terminally treating chamber from the terminally treating gas supply device and thereby forming plasma for terminating treatment.

This third silicon dot forming apparatus can implement the third silicon dot forming method.

The third silicon dot forming apparatus may further include a control portion comparing the emission intensity ratio (Si(288 nm)/Hβ) obtained by the optical emission spectroscopic analyzer for plasma with a reference emission intensity ratio (Si(288 nm)/Hβ) predetermined within a range not exceeding 10.0, and controlling at least one of a power output of the first high-frequency power applying device, a supply amount of the hydrogen gas supplied from the hydrogen gas supply device into the silicon dot forming chamber and an exhaust amount of the first exhaust device such that the emission intensity ratio (Si(288 nm)/Hβ) in the plasma in the silicon dot forming chamber changes toward the reference emission intensity ratio.

The reference emission intensity ratio may be determined in a range not exceeding 3.0 or 0.5.

The first and second high-frequency power applying devices may partially or entirely share the same structure. The first and second exhaust devices may partially or entirely share the same structure.

(4) Fourth Silicon Dot Forming Apparatus

A silicon dot forming apparatus including:

a silicon dot forming chamber having a holder for holding a silicon dot formation target substrate;

a hydrogen gas supply device supplying a hydrogen gas into the silicon dot forming chamber;

a silane-containing gas supply device supplying a silane-containing gas into the silicon dot forming chamber;

a first exhaust device exhausting a gas from the silicon dot forming chamber;

a first high-frequency power applying device applying a high-frequency power to the gases supplied into the silicon dot forming chamber from the hydrogen gas supply device and the silane-containing gas supply device, and thereby forming plasma for silicon dot formation;

an optical emission spectroscopic analyzer for plasma obtaining a ratio (Si(288 nm)/Hβ) between an emission intensity Si(288 nm) of silicon atoms at a wavelength of 288 nm and an emission intensity Hβ of hydrogen atoms at a wavelength of 484 nm in emission of the plasma for silicon dot formation in the silicon dot forming chamber;

a terminally treating chamber for terminating treatment of silicon dots which chamber has a holder holding a substrate having the silicon dots formed thereon;

a terminally treating gas supply device supplying at least one terminally treating gas selected from an oxygen-containing gas and a nitrogen-containing gas into the terminally treating chamber;

a second exhaust device exhausting a gas from the terminally treating chamber; and

a second high-frequency power applying device applying a high-frequency power to the terminally treating gas supplied into the terminally treating chamber from the terminally treating gas supply device, and thereby forming plasma for terminating treatment.

This fourth silicon dot forming apparatus can implement the fourth silicon dot forming method.

The fourth silicon dot forming apparatus may further include a control portion comparing the emission intensity ratio (Si(288 nm)/Hβ) obtained by the optical emission spectroscopic analyzer for plasma with a reference emission intensity ratio (Si(288 nm)/Hβ) predetermined within a range not exceeding 10.0 and controlling at least one of a power output of the first high-frequency power applying device, a supply amount of the hydrogen gas supplied from the hydrogen gas supply device into the silicon dot forming chamber, a supply amount of the silane-containing gas supplied from the silane-containing gas supply device into the silicon dot forming chamber, and an exhaust amount of the first exhaust device such that the emission intensity ratio (Si(288 nm)/Hβ) of the plasma in the silicon dot forming chamber changes toward the reference emission intensity ratio.

The reference emission intensity ratio may be determined in a range not exceeding 3.0 or 0.5.

The first and second high-frequency power applying devices may partially or entirely share the same structure.

The first and second exhaust devices may partially or entirely share the same structure.

In any case, the silicon sputter target may be arranged in the silicon dot forming chamber.

In any one of the first to fourth silicon dot forming apparatuses described above, the apparatus may include, as an example of the optical emission spectroscopic analyzer for plasma, a first detecting portion detecting the emission intensity Si(288 nm) of silicon atoms at a wavelength of 288 nm in plasma emission, a second detecting portion detecting the emission intensity Hβ of hydrogen atoms at a wavelength of 484 nm in the plasma emission, and an arithmetic portion obtaining the ratio (Si(288 nm)/Hβ) between the emission intensity Si(288 nm) detected by the first detecting portion and the emission intensity Hβ detected by the second detecting portion.

In any one of the first to fourth silicon dot forming apparatuses described above, the silicon dot forming chamber may be allowed to serve as both the silicon dot forming chamber and the terminally treating chamber. The latter chamber may be provided independently of the former chamber.

In another embodiment, the terminally treating chamber may be communicated with the silicon dot forming chamber. When the silicon dot forming chamber is allowed to serve also as the terminally treating chamber, or when the terminally treating chamber is communicated with the silicon dot forming chamber, the silicon dots can be inhibited from contamination prior to terminating treatment.

In the case where the terminally treating chamber is communicated with the silicon dot forming chamber, the two chambers may be communicated with each other either directly or via a substrate transferring chamber having a substrate transferring device.

Embodiments of the invention will be described below with reference to the drawings.

[1] Example of the Terminally Treated Silicon Dot Forming Apparatus.

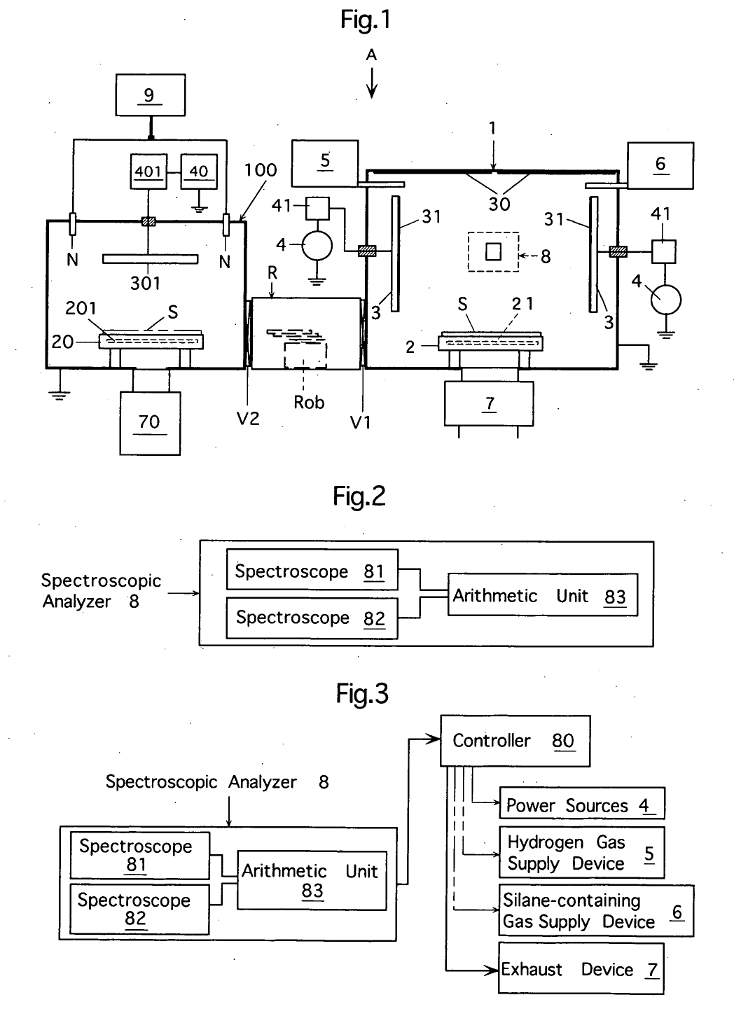

FIG. 1 shows a schematic structure of an example of the silicon dot forming apparatus for use in implementing the silicon dot forming method according to the invention.

The apparatus A shown in FIG. 1 is intended to form silicon dots on a flat type silicon dot formation target substrate (namely, substrate S). The apparatus A has a silicon dot forming chamber 1 and a terminally treating chamber 100.

A substrate holder 2 is provided in the silicon dot forming chamber 1 which includes a pair of discharge electrodes 3 laterally spaced from each other in a region above the substrate holder 2. Each of the discharge electrodes 3 is connected to a high-frequency power source 4 via a matching box 41. The power sources 4, the matching boxes 41, and the electrodes 3 constitute a high-fluency power applying device.

Connected to the chamber 1 are a gas supply device 5 for supplying a hydrogen gas into the chamber 1, and a gas supply device 6 for supplying a silane-containing gas containing silicon (i.e., having silicon atoms) into the chamber 1. Further, an exhaust device 7 is connected to the chamber 1 for exhausting a gas from the chamber 1. The chamber 1 is provided with an optical emission spectroscopic analyzer 8 for plasma for measuring a state of plasma produced in the chamber 1 and the like.

The silane-containing gas may be monosilane (SiH₄), and also may be disilane (Si₂H₆), silicon fluoride (SiF₄), silicon tetrachloride (SiCl₄), dichlorosilane (SiH₂Cl₂) or the like.

The substrate holder 2 is provided with a heater 21 for heating the substrate.

The electrodes 3 have a silicon film 31 at its inner side surface in advance which is made to function as an insulating film. Silicon sputter targets 30 are provided in advance on inner surfaces of a top wall in the chamber 1.

Each of the electrodes 3 is arranged perpendicularly to the substrate surface (more specifically, perpendicularly to a surface including the surface of the substrate S).

The silicon sputter target 30 can be selected from, e.g., commercially available silicon sputter targets (1)-(3) described below depending on the use or the like of the silicon dots to be formed.

(1) A target made of single-crystalline silicon, a target made of polycrystalline silicon, a target made of microcrystalline silicon, a target made of amorphous silicon or a target made of a combination of two or more of them.

(2) A silicon sputter target which is made of one of the materials in the above item (1), and in which a content of each of phosphorus (P), boron (B) and germanium (Ge) is lower than 10 ppm.

(3) A silicon sputter target made of one of the materials in the above item (1), and exhibiting a predetermined resistivity (e.g., a silicon sputter target exhibiting the resistivity from 0.001 ohm·cm to 50 ohm·cm)

The power source 4 is of an output-variable type and can supply a high-frequency power at a frequency of 60 MHz. The frequency is not restricted to 60 MHz and may be in a range of, e.g., about 13.56 MHz to about 100 MHz or in a higher range.

Each of the chamber 1 and the substrate holder 2 is grounded.

The gas supply device 5 includes a hydrogen gas source as well as a valve, a mass flow controller for flow rate control, etc. (which are not shown in the figure).

The gas supply device 6 can supply a silane-containing gas such as monosilane (SiH₄), and includes a gas source of the monosilane as well as a valve, a massflow controller for flow control and the like which are not shown in the figure.

The exhaust device 7 includes an exhaust pump as well as a conductance valve for controlling an exhaust flow rate and the like.

The optical emission spectroscopic analyzer 8 for plasma can detect the emission spectrums of products of gas decomposition, and the emission intensity ratio (Si(288 nm)/Hβ) can be obtained based on a result of the detection.

A specific example of the optical emission spectroscopic analyzer 8 for plasma may include, as shown in FIG. 2, a spectroscope 81 detecting the emission intensity Si(288 nm) of silicon atoms at a wavelength of 288 nm in plasma emission in the silicon dot forming chamber 1, a spectroscope 82 detecting the emission intensity Hβ of hydrogen atoms at a wavelength of 484 nm in the plasma emission, and an arithmetic unit 83 obtaining the ratio (Si(288 nm)/Hβ) between the emission intensity Si(288 nm) and the emission intensity Hβ detected by the spectroscopes 81, 82. Instead of the spectroscopes 81 and 82, photosensors each provided with a filter may be employed.

In the terminally treating chamber 100, a substrate holder 20 and a flat type high-frequency discharge electrode 301 above the holder 20 are disposed. Connected to the electrode 301 is a high-frequency power source 40 via a matching box 401.

An exhaust device 70 for exhausting a gas from the chamber 100 is connected to the terminally treating chamber 100, and a terminally treating gas supply device 9 supplying a terminally treating gas into the chamber 100 is connected to the chamber 100.

The substrate holder 20 is a holder for holding the substrate S having silicon dots formed in the silicon dot forming chamber 1 and transferred to the chamber 1 as described later, and has a heater 201 for heating the substrate. The holder 20 as well as the chamber 100 are grounded.

The power source 40 is of an output-variable type, and can supply a high-frequency power at a frequency of, e.g., 13.56 MHz. The frequency need not be restricted to 13.56 MHz.

The electrode 301, the matching box 401 and the power source 40 compose a high-frequency power applying device applying power to the terminally treating gas to form plasma for terminating treatment.

The exhaust device 70 includes an exhaust pump as well as a conductance valve for controlling an exhaust flow rate and the like.

The terminally treating gas supply device 9 can supply an oxygen gas or a nitrogen gas as the terminally treating gas through nozzles N into the chamber 100 in this example. The gas supply device 9 includes a gas source as well as a valve, a mass flow controller controlling the flow rate, etc. which are not shown in the figure.

The terminally treating chamber 100 is communicated with the silicon dot forming chamber 1 via a substrate transferring chamber R. An opening or shutting gate valve V1 is disposed between the substrate transferring chamber R and the chamber 1, and an opening or shutting gate valve V2 is disposed between the substrate transferring chamber R and the chamber 100. A substrate transferring robot Rob is arranged in the substrate transferring chamber R.

Formation of Silicon Dot Terminally Treated By Apparatus A

Description will be given on an example of forming silicon dots terminally treated with oxygen or nitrogen on the substrate S by the apparatus A.

(2-1) Practicing the Silicon Dot Forming Step

(2-1-1) An Embodiment of the Silicon Dot Forming Step (Example of Using Only an Hydrogen Gas)

When forming the silicon dots, the pressure in the silicon dot forming chamber 1 is kept in a range from 0.1 Pa to 10.0 Pa. The silicon dot forming chamber pressure can be sensed, e.g., by a pressure sensor (not shown) connected to the chamber.

First, prior to the silicon dot formation, the exhaust device 7 starts exhausting from the chamber 1. The conductance valve (not shown) in the exhaust device 7 is adjusted in advance in view of the above pressure from 0.1 Pa to 10.0 Pa for the silicon dot formation in the chamber 1.

When the exhaust device 7 lowers the pressure in the chamber 1 to a predetermined value or lower, the gas supply device 5 starts supplying of the hydrogen gas into the chamber 1, and the power sources 4 apply the power to the electrodes 3 to produce plasma from the supplied hydrogen gas.

From the gas plasma thus produced, the optical emission spectroscopic analyzer 8 for plasma calculates the emission intensity ratio (Si(288 nm)/Hβ), and determines the magnitude of the high-frequency power, the amount of supplied hydrogen gas, the pressure in the chamber 1 and the like such that the above calculated ratio may change toward a predetermined value (reference emission intensity ratio) in a range from 0.1 to 10.0, and more preferably a range from 0.1 to 3.0, or from 0.1 to 0.5.

The magnitude of the high-frequency power is determined such that the power density [(applied power (W: watt))/(capacity of chamber 1 (L: liter))] of the high-frequency power applied to the electrodes 3 preferably falls within a range from 5 W/L to 100 W/L, or in a range from 5 W/L to 50 W/L.

After determining the silicon dot formation conditions as described above, the silicon dots are formed according to the conditions.

When forming the silicon dots, the silicon dot formation target substrate S is arranged on the substrate holder 2 in the chamber 1, and is heated by the heater 21 to a temperature (e.g., of 400 deg. C.) not exceeding 500 deg. C. The exhaust device 7 operates to maintain the pressure for the silicon dot formation in the chamber 1, and the gas supply device 5 supplies the hydrogen gas into the chamber 1 so that the power sources 4 apply the high-frequency power to the discharge electrodes 3 to produce the plasma from the supplied hydrogen gas.

In this manner, the ratio (Si(288 nm)/Hβ) between the emission intensity Si(288 nm) of silicon atoms at a wavelength of 288 nm and the emission intensity Hβ of hydrogen atoms at a wavelength of 484 nm in plasma emission falls within a range from 0.1 to 10.0, and more preferably within a range from 0.1 to 3.0, or from 0.1 to 0.5, and thus the plasma having the foregoing reference emission intensity ratio or substantially having the foregoing reference emission intensity ratio is generated. Chemical sputtering (reactive sputtering) is effected with the above plasma on the silicon sputter targets 30 on the inner surfaces of the top wall of the chamber 1 and the like so that silicon dots having the particle diameters of 20 nm or smaller and exhibiting the crystallinity are formed on the surface of the substrate S.

(2-1-2) Another Embodiment of Silicon Dot Forming Step (Example Using a Hydrogen Gas and a Silane-Containing Gas)

When forming the silicon dots as described above, the silane-containing gas that can be supplied from the gas supply device 6 is not used, and only the hydrogen gas is used. However, the silicon dots can be formed by supplying the silane-containing gas from the gas supply device 6 while supplying the hydrogen gas from the gas supply device 5 into the silicon dot forming chamber 1. When using both the silane-containing gas and the hydrogen gas, the silicon dots can be formed without employing the silicon sputter targets 30.

When employing the silane-containing gas together with the silicon sputter target(s) 30 or without using the target(s) 30, the plasma can be generated such that the ratio (Si(288 nm)/Hβ) between the emission intensity Si(288 nm) of silicon atoms at a wavelength of 288 nm and the emission intensity Hβ of hydrogen atoms at a wavelength of 484 nm in plasma emission falls within a range from 0.1 to 10.0, and more preferably within a range from 0.1 to 3.0, or from 0.1 to 0.5. Even when the silicon sputter target 30 is not employed, the silicon dots having the particle diameters of 20 nm or smaller and exhibiting the crystallinity can be formed on the surface of the substrate S.

When employing the silicon sputter target 30, the chemical sputtering effected on the silicon sputter target 30 on the inner surfaces of the top wall and the like with the plasma can be additionally employed so that the silicon dots having the particle diameters of 20 nm or lower and exhibiting the crystallinity can be formed on the surface of the substrate S.

In any one of the above cases, the pressure in the silicon dot forming chamber 1 is maintained in a range from 0.1 Pa to 10.0 Pa, and the magnitude of the high-frequency power, the amounts of supplied hydrogen gas and silane-containing gas, the pressure in the chamber 1 and the like are determined for the silicon dot formation such that the emission intensity ratio (Si(288 nm)/Hβ) calculated by the optical emission spectroscopic analyzer 8 for plasma may attain the value (the reference emission intensity ratio) falling within a range from 0.1 to 10.0, and more preferably a range from 0.1 to 3.0 or from 0.1 to 0.5, or may substantially attain the reference emission intensity ratio.

The magnitude of the high-frequency power is determined such that the power density (applied power (W: watt))/(silicon dot forming chamber capacity (L: liter)) of the high-frequency power applied to the electrodes 3 falls within a range from 5 W/L to 100 W/L, or in a range from 5 W/L to 50 W/L, and the silicon dot formation may be performed under the silicon dot formation conditions thus determined.

The supply flow rate ratio (silane-containing gas flow rate)/(hydrogen gas flow rate) between the silane-containing gas and the hydrogen gas supplied into the silicon dot forming chamber 1 is determined in a range from 1/200 to 1/30. The supply flow rate of the silane-containing gas is, e.g., in a range from 1 sccm to 5 sccm, and the ratio of (silane-containing gas supply flow rate (sccm))/(silicon dot forming chamber capacity (liter)) may be in a range from 1/200 to 1/30. When the supply flow rate of the silane-containing gas is substantially in a range from 1 sccm to 5 sccm, the appropriate supply flow rate of the hydrogen gas is, e.g., in a range from 150 sccm to 200 sccm.

(2-2) Execution of Terminally Treating Step

Next, the substrate bearing the silicon dots formed thereon in this way is transferred into the terminally treating chamber 100 so that the silicon dots are terminally treated with oxygen or nitrogen.

In this operation, the substrate is placed into the chamber 100 as follows. The gate valve V1 is opened and the substrate S supported on the holder 2 is taken out by the robot Rob. Then the substrate S is drawn into the substrate transferring chamber R and the gate valve V1 is closed. Subsequently the gate valve V2 is opened and the substrate S is placed onto the holder 20 in the chamber 100. Thereafter a movable portion of the robot is retracted into the substrate transferring chamber R, then the gate valve V2 is closed, and the terminating treatment is carried out in the chamber 100.

In the terminating treatment in the terminally treating chamber 100, the substrate S is heated with a heater 201 to a temperature suitable as the terminally treating temperature. The exhaust device 70 starts exhausting from inside of the chamber 100. When the exhaust device 70 lowers the pressure in the chamber 100 to a pressure lower than the terminally treating pressure, a determined amount of the terminally treating gas (oxygen gas or hydrogen gas in this example) is supplied into the chamber 100 from the terminally treating gas supply device 9. A high-frequency power is applied from the output-variable power source 40 to the high-frequency discharge electrode 301, whereby plasma is produced from the supplied gas by a capacitive coupling method.

With the terminally treating plasma thus produced, the terminating treatment with oxygen or nitrogen is executed at the surfaces of the silicon dots on the substrate S to obtain terminally treated silicon dots.

The terminally treating pressure in the terminally treating step is, for example, from about 0.2 Pa to about 7.0 Pa although not limited thereto.

For example, the heating temperature of the substrate in the terminally treating step may be selected from a range from room temperature to about 500 deg. C. in view of a meaningful low temperature at which silicon dots are formed as well as heat resistance of the substrate S.

[Another Example of Electrodes]

In the silicon dot forming apparatus A described above, the electrode used is of flat form capacitive coupling type. An electrode of an inductive coupling type may be employed in the silicon dot forming chamber 1 and/or the terminally treating chamber 100. In the case of the electrode of an inductive coupling type, the electrode of an inductive coupling type may have various forms such as a rod-like form or a coil-like form. The number of the electrode of the inductive coupling type is not restricted.

In the case of employing an electrode of an inductive coupling type as well as the silicon sputter target for the silicon dot forming chamber 1, the silicon sputter target may be arranged along the whole of or a part of the inner surface of the chamber wall, may be independently arranged in the chamber or may be arranged in both ways in spite of whether the electrode is arranged inside the chamber or outside the chamber.

In the apparatus A, the chamber 1 may be heated by heating means (e.g., band heater or heating jacket internally passing a heat medium) for heating the silicon dot forming chamber 1 (although not shown in the figure) to heat the silicon sputter target to 80 deg. C. or higher for promoting sputtering of the silicon sputter target.

### [4] Another Example of Control of Emission Intensity Ratio [Si(288 nm)/Hβ)]

In the step of forming the silicon dots as described above, manual operations are performed with reference to the emission intensity ratio obtained by the optical emission spectroscopic analyzer 8 for plasma for controlling the output of the output-variable power sources 4, the hydrogen gas supply amount of the hydrogen gas supply device 5 (or the hydrogen gas supply amount of the hydrogen gas supply device 5 and the silane-containing gas supply amount of the silane-containing gas supply device 6), the exhaust amount of the exhaust device 7 and others.

However, as shown in FIG. 3, the emission intensity ratio (Si(288 nm)/Hβ) obtained by the arithmetic unit 83 of the optical emission spectroscopic analyzer 8 for plasma may be applied to a controller 80. The controller 80 may be configured as follows. The controller 80 determines whether the emission intensity ratio (Si(288 nm)/Hβ) applied from the arithmetic unit 83 is the predetermined reference emission intensity ratio or not. When it is different from the reference emission intensity ratio, the controller 80 controls at least one of the output of the output-variable power sources 4, the supply amount of the hydrogen gas supplied from the hydrogen gas supply device 5, the supply amount of the silane-containing gas supplied from the silane-containing gas supply device 6 and the exhaust amount of the exhaust device 7 to attain the reference emission intensity ratio.

As a specific example, the controller 80 may be configured such that the controller 80 controls the exhaust amount of the exhaust device 7 by controlling the conductance valve thereof, and thereby controls the gas pressure in the silicon dot forming chamber 1 to attain the foregoing reference emission intensity ratio.

In this case, the output of the output-variable power sources 4, the hydrogen gas supply amount of the hydrogen gas supply device 5 (or the hydrogen gas supply amount of the hydrogen gas supply device 5 and the silane-containing gas supply amount of the silane-containing gas supply device 6) and the exhaust amount of the exhaust device 7 are controlled based on the initial values of the power output, the hydrogen gas supply amount (or supply amounts of the hydrogen gas and the silane-containing gas) and the exhaust amount which can achieve the reference emission intensity ratio or a value close to it, and are determined in advance by experiments or the like.

When determining the above initial values, the exhaust amount of the exhaust device 7 is determined such that the pressure in the silicon dot forming chamber 1 falls within a range from 0.1 Pa to 10.0 Pa.

The output of the power sources 4 is determined such that the power density of the high-frequency power applied to the electrodes 3 may fall within a range from 5 W/L to 100 W/L, or from 5 W/L to 50 W/L.

When both the hydrogen gas and silane-containing gas are used as the gases for plasma formation, the gas supply flow rate ratio (silane-containing gas flow rate)/(hydrogen gas flow rate) into the silicon dot forming chamber 1 is determined in a range from 1/200 to 1/30. For example, the supply flow rate of the silane-containing gas is 1 sccm-5 sccm, and (silane-containing gas supply flow rate (sccm))/(silicon dot forming chamber capacity (liter)) is determined in a range from 1/200 to 1/30.

The output of the power source 4 and the hydrogen gas supply amount of the hydrogen gas supply device 5 (or the hydrogen gas supply amount of the hydrogen gas supply device 5 and the silane-containing gas supply amount of the silane-containing gas supply device 6) will be maintained at the initial values thus determined, and the exhaust amount of the exhaust device 7 is controlled by the controller 80 to attain the reference emission intensity ratio.

### [5] Another Example of Silicon Sputter Target

In the step of forming the silicon dots as described above, the silicon sputter target is formed of a commercially available target, and is arranged in the silicon dot forming chamber 1 in an independent step. However, by employing the silicon sputter target that has not been exposed to an ambient air, it is possible to form the silicon dots that are further protected from unintended mixing of impurities.

More specifically, in the apparatus A described above, the hydrogen gas and silane-containing gas are supplied into the silicon dot forming chamber 1 when the substrate S is not yet arranged therein, and the power sources 4 apply the high-frequency power to these gases to form the plasma, which forms a silicon film on the inner wall of the silicon dot forming chamber 1. When forming the silicon film, it is preferable to heat the chamber wall by an external heater.

Thereafter, the substrate S is arranged in the chamber 1, and the chemical sputtering is effected on the sputter target formed of the silicon film with the plasma produced from the hydrogen gas so that the silicon dots are formed on the substrate S as described above.

In the process of forming the silicon film to be used as the silicon sputter target, it is desired for forming the silicon film of good quality that the emission intensity ratio (Si(288 nm)/Hβ) in the plasma falls within a range from 0.1 to 10.0, and more preferably within a range from 0.1 to 3.0, or from 0.1 to 0.5.

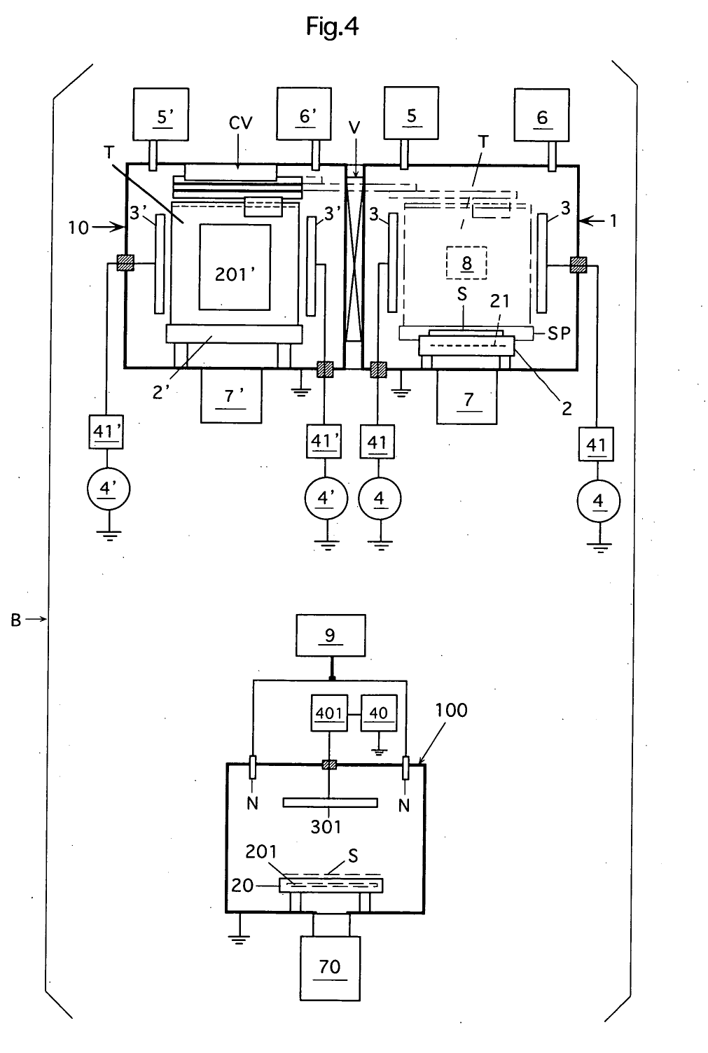

For another method, another example B of the silicon dot forming apparatus shown in FIG. 4 may be used, and the following method may be conducted.

That is, as shown in FIG. 4, a target forming chamber 10 for forming a silicon sputter target is communicated with the silicon dot forming chamber 1 via a gate valve V in an airtight fashion with respect to an ambient air.

A target substrate T is arranged on a holder 2′ in the chamber 10, and an exhaust device 7′ exhausts a gas from the chamber 10 to keep a predetermined deposition pressure. A hydrogen gas supply device 5′ and a silane-containing gas supply device 6′ supply the hydrogen gas and the silane-containing gas, respectively into the chamber 10. Further, an output-variable power sources 4′ apply a high-frequency power to electrodes 31 in the chamber through matching boxes 41′ to form plasma. By this plasma, a silicon film is formed on the target substrate T heated by a heater 201′.

Thereafter, the gate valve V is opened, and a transferring device CV transfers the target substrate T bearing the silicon film into the silicon dot forming chamber 1, and sets it on a base SP in the chamber 1. Then, the transferring device CV returns, and the gate valve V is airtightly closed. One of the silicon dot forming methods already described is executed to form silicon dots on the substrate S arranged in the chamber 1, using the target substrate T bearing the silicon film as the silicon sputter target in the chamber 1.

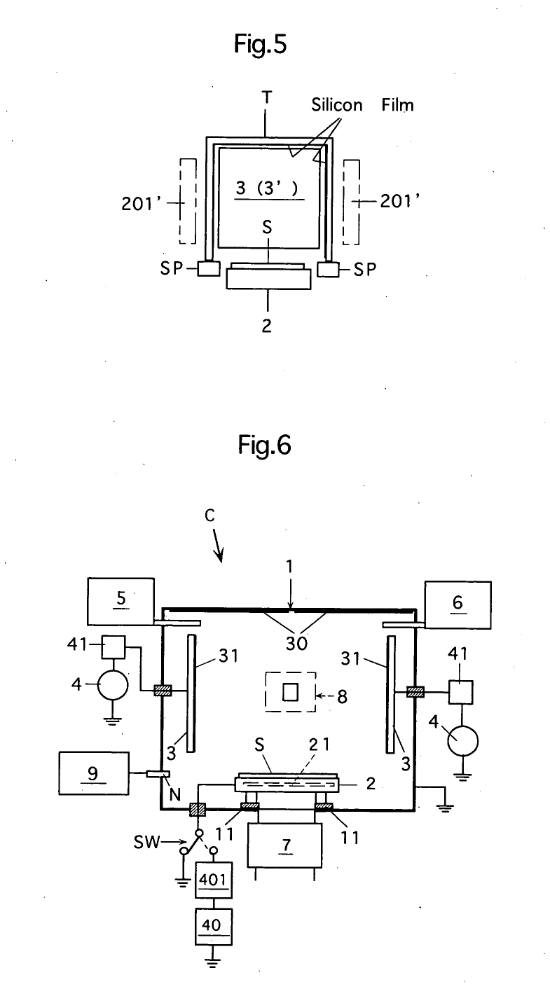

FIG. 5 shows positional relationships of the target substrate T with respect to the electrodes 3 (or 3′), the heater 201′ in the chamber 10, the base SP in the chamber 1, the substrate S and the like. The target substrate T has a substantially inverted U-shaped section for obtaining the silicon sputter target of a large area as shown in FIG. 5, although it may have another form.

The transferring device CV can transfer the substrate T without colliding the substrate T against the electrodes or the like. The transferring device CV may have various structures provided that it can bring the substrate T into the silicon dot forming chamber 1 and can set it therein. For example, the transferring device CV may have a structure having an extensible arm for holding the substrate T.

When forming a silicon film on the target substrate in the chamber 10, it is desired to form a silicon film of good quality that the emission intensity ratio (Si(288 nm)/Hβ) of the plasma falls within a range from 0.1 to 10.0, and more preferably within a range from 0.1 to 3.0, or from 0.1 to 0.5.

In this case, the output of the power sources 4′, the hydrogen gas supply amount of the hydrogen gas supply device 5′, the silane-containing gas supply amount of the silane-containing gas supply device 6′ and the exhaust amount of the exhaust device 7′ for the chamber 10 may be controlled similarly to the case of forming the silicon dots on the substrate S with the hydrogen gas and the silane-containing gas in the apparatus A. Manual control may be performed, and automatic control with the controller may also be performed.

In connection with the transferring device, a substrate transferring chamber provided with a substrate transferring device may be arranged between the chambers 10 and 1, and the chamber provided with the transferring device may be connected to each of the chambers 10 and 1 via a gate valve.

In the chamber 10, an inductively coupled plasma may be formed using a high-frequency discharge antenna as the high-frequency discharge electrode.

In the apparatus B shown in FIG. 4, the terminally treating chamber 100 is arranged independently of the silicon dot forming chamber 1. However, the chamber 100 may be connected to the silicon dot forming chamber 1 as in the case of the apparatus A.

### [6] EXPERIMENT

Description will be given on experimental examples of formation of terminally treated silicon dots.

### (1) Experimental Example 1 (Formation of Silicon Dots Terminally Treated with Oxygen)

The silicon dot forming apparatus of the type shown in FIG. 1 was used.

(1-1) Silicon Dot Forming Step in the Silicon Dot Forming Chamber

Silicon dots were formed directly on the substrate using a hydrogen gas and monosilane gas without using a silicon sputter target. Dot formation conditions were as follows:
Substrate: silicon wafer coated with oxide film (SiO₂)
Chamber capacity: 180 liters
High-frequency power source: 60 MHz, 6 kW
Power density: 33 W/L
Substrate temperature: 400 deg. C. (400° C.)
Inner pressure of chamber: 0.6 Pa
Silane supply amount: 3 sccm
Hydrogen supply amount: 150 sccm
Si(288 nm)/Hβ: 0.5
   (1-2) Terminally Treating Step in the Terminally Treating Chamber
Substrate temperature: 400 deg. C. (400° C.)
Oxygen gas supply amount: 100 sccm
High-frequency power source: 13.56 MHz, 1 kW
Terminally treating pressure: 0.6 Pa
Treating time: 5 minutes.

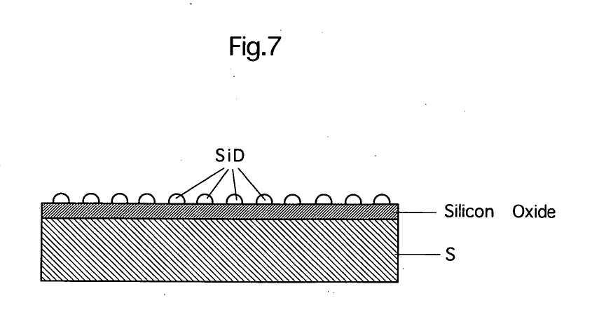

The section of the thus obtained substrate bearing the silicon dots terminally treated and formed thereon was observed with a transmission electron microscope (TEM), and it was confirmed that the silicon dots having uniform particle diameters and exhibiting a uniform distribution and a high density state were formed independently of each other. From the TEM images, the particle diameters of the silicon dots of 50 in number were measured. It was confirmed that the average of the measured values was 7 nm, and it was confirmed that the silicon dots having particle diameters not exceeding 20 nm and particularly not exceeding 10 nm were formed. The dot density was about 1.4×10¹² pcs(pieces)/cm². FIG. 7 schematically shows an example of the silicon dot structure provided with silicon dots SiD formed on the substrate S.

### (2) Experimental Example 2 (Formation of Silicon Dots Terminally Treated with Oxygen)

The silicon dot forming apparatus of the type shown in FIG. 1 was used.

(2-1) Silicon Dot Forming Step in the Silicon Dot Forming Chamber

Silicon dots were formed directly on the substrate with a hydrogen gas and monosilane gas and also with a silicon sputter target. Dot formation conditions were as follows:
Silicon sputter target: amorphous silicon sputter target
Substrate: silicon wafer coated with oxide film (SiO₂)
Chamber capacity: 180 liters
High-frequency power source: 60 MHz, 4 kW
Power density: 22 W/L
Substrate temperature: 400 deg. C.
Inner pressure of chamber: 0.6 Pa
Silane supply amount: 1 sccm
Hydrogen supply amount: 150 sccm
Si(288 nm)/Hβ: 0.3
   (2-2) Terminally Treating Step in the Terminally Treating Chamber
Substrate temperature: 400 deg. C.
Oxygen gas supply amount: 100 sccm
High-frequency power source: 13.56 MHz, 1 kW
Terminally treating pressure: 0.6 Pa
Treating time: 1 minute.

The section of the thus obtained substrate bearing the silicon dots terminally treated and formed thereon was observed with the transmission electron microscope (TEM), and it was confirmed that the silicon dots having uniform particle diameters and exhibiting a uniform distribution and a high density state were formed independently of each other. From the TEM images, the particle diameters of the silicon dots of 50 in number were measured. It was confirmed that the average of the measured values was 10 nm, and it was confirmed that the silicon dots having particle diameters not exceeding 20 nm were formed. The dot density was about 1.0×10¹² pcs(pieces)/cm².

### (3) Experimental Example 3 (Formation of Silicon Dots Terminally Treated with Oxygen)

The silicon dot forming apparatus of the type shown in FIG. 1 was used.

(3-1) Silicon Dot Forming Step in the Silicon Dot Forming Chamber

Silicon dots were formed directly on the substrate without using a silane gas but using a hydrogen gas and a silicon sputter target. Dot formation conditions were as follows:
Silicon sputter target: monocrystalline silicon sputter target
Substrate: silicon wafer coated with oxide film (SiO₂)
Chamber capacity: 180 liters
High-frequency power source: 60 MHz, 4 kW
Power density: 22 W/L
Substrate temperature: 400 deg. C.
Inner pressure of chamber: 0.6 Pa
Hydrogen supply amount: 100 sccm
Si(288 nm)/Hβ: 0.2
   (3-2) Terminally Treating Step in the Terminally Treating Chamber
Substrate temperature: 400 deg. C.
Oxygen gas supply amount: 100 sccm
High-frequency power source: 13.56 MHz, 2 kW
Terminally treating pressure: 0.6 Pa
Treating time: 10 minutes.

The section of the thus obtained substrate bearing the silicon dots terminally treated and formed thereon was observed with the transmission electron microscope (TEM), and it was confirmed that the silicon dots having uniform particle diameters and exhibiting a uniform distribution and a high density state were formed independently of each other. From the TEM images, the particle diameters of the silicon dots of 50 in number were measured. It was confirmed that the average of the measured values was 5 nm, and it was confirmed that the silicon dots having particle diameters not exceeding 20 nm and particularly not exceeding 10 nm were formed. The dot density was about 2.0×10¹² pcs(pieces)/cm².

### (4) Experimental Example 4 (Formation of Silicon Dots Terminally Treated with Oxygen)

The silicon dot forming apparatus of the type shown in FIG. 1 was used.

(4-1) Silicon Dot Forming Step in the Silicon Dot Forming Chamber

A silicon film was formed on the inner wall of the silicon dot forming chamber 1, and silicon dots were formed using the silicon film as the sputter target. Silicon film formation conditions and dot formation conditions were as follows:

Silicon Film Formation Conditions

Area of inner wall of chamber: about 3 m²
Chamber capacity: 440 liters
High-frequency power source: 13.56 MHz, 10 kW
Power density: 23 W/L
Inner chamber wall temperature: 80 deg. C. (heated by a heater disposed in the chamber 1)
Inner pressure of chamber: 0.67 Pa
Monosilane supply amount: 100 sccm
Hydrogen supply amount: 150 sccm
Si(288 nm)/HP: 2.0
   Dot Formation Conditions
Substrate: silicon wafer coated with oxide film (SiO₂)
Chamber capacity: 440 liters
High-frequency power source: 13.56 MHz, 5 kW
Power density: 11 W/L
Inner wall temperature: 80 deg. C. (heated by a heater disposed in the chamber 1)
Substrate temperature: 430 deg. C.
Internal pressure of chamber: 0.67 Pa
Hydrogen supply amount: 150 sccm (monosilane gas not used)
Si(288 nm)/Hβ: 1.5
   (4-2) Terminally Treating Step in the Terminally Treating Chamber
Substrate temperature: 400 deg. C.
Oxygen supply amount: 100 sccm
High-frequency power source: 13.56 MHz, 2 kW
Terminally treating pressure: 0.6 Pa
Treating time: 5 minutes.

The section of the thus obtained substrate bearing the silicon dots terminally treated and formed thereon was observed with the transmission electron microscope (TEM), and it was confirmed that the silicon dots having uniform particle diameters and exhibiting a uniform distribution and a high density state were formed independently of each other. It was confirmed that smaller particle diameters were 5 nm to 6 nm and larger particle diameters were 9 nm to 11 nm. From the TEM images, the particle diameters of the silicon dots of 50 in number were measured. It was confirmed that the average of the measured values was 8 nm, and it was confirmed that the silicon dots having particle diameters not exceeding 10 nm were substantially formed. The dot density was about 7.3×10¹¹ pcs(pieces)/cm².

### (5) Experimental Example 5 (Formation of Silicon Dots Terminally Treated with Oxygen)

The silicon dot forming apparatus of the type shown in FIG. 1 was used.

(5-1) Silicon Dot Forming Step in the Silicon Dot Forming Chamber

First a silicon film was formed on the inner wall of the silicon dot forming chamber 1 under the silicon film formation conditions of the Experimental Example 4, and silicon dots were formed using the silicon film as the sputter target. The dot formation conditions were the same as the Experimental Example 4 except that the pressure in the chamber was 1.34 Pa and Si(288 nm)/Hβ was 2.5.

(5-2) Terminally Treating Step in the Terminally Treating Chamber

Terminating treatment was conducted in the same manner as in the Experimental Example 4.

The section of the thus obtained substrate bearing the silicon dots terminally treated and formed thereon was observed with the transmission electron microscope (TEM), and it was confirmed that the silicon dots having uniform particle diameters and exhibiting a uniform distribution and a high density state were formed independently of each other. From the TEM images, the particle diameters of the silicon dots of 50 in number were measured. It was confirmed that the average of the measured values was 10 nm, and it was confirmed that the silicon dots having particle diameters not exceeding 10 nm were substantially formed. The dot density was about 7.0×10¹¹ pcs(pieces)/cm².

### (6) Experimental Example 6 (Formation of Silicon Dots Terminally Treated with Oxygen)

The silicon dot forming apparatus of the type shown in FIG. 1 was used.

(6-1) Silicon Dot Forming Step in the Silicon Dot Forming Chamber

First a silicon film was formed on the inner wall of the silicon dot forming chamber 1 under the silicon film formation conditions in the Experimental Example 4 and then silicon dots were formed from the silicon film as the silicon sputter target. The dot formation conditions were the same as the Experimental Example 4 except that the inner pressure in the chamber was 2.68 Pa and Si(288 nm)/Hβ was 4.6.

(6-2) Terminally Treating Step in the Terminally Treating Chamber

Terminating treatment was conducted in the same manner as the Experimental Example 4.

The section of the thus obtained substrate bearing the silicon dots terminally treated and formed thereon was observed with the transmission electron microscope (TEM), and it was confirmed that the silicon dots having uniform particle diameters and exhibiting a uniform distribution and a high density state were formed independently of each other. From the TEM images, the particle diameters of the silicon dots of 50 in number were measured. It was confirmed that the average of the measured values was 13 nm, and it was confirmed that the silicon dots having particle diameters not exceeding 20 nm were substantially formed. The dot density was about 6.5×10¹¹ pcs(pieces)/cm².

### (7) Experimental Example 7 (Formation of Silicon Dots Terminally Treated with Oxygen)

The silicon dot forming apparatus of the type shown in FIG. 1 was used.

(7-1) Silicon Dot Forming Step in the Silicon Dot Forming Chamber

First a silicon film was formed on the inner wall of the silicon dot forming chamber 1 under the silicon film formation conditions in the Experimental Example 4 and then silicon dots were formed from the silicon film as the silicon sputter target. The dot formation conditions were the same as the Experimental Example 4 except that the inner pressure in the chamber was 6.70 Pa and Si(288 nm)/Hβ was 8.2.

(7-2) Terminally Treating Step in the Terminally Treating Chamber

Terminating treatment was conducted in the same manner as the Experimental Example 4.

The section of the thus obtained substrate bearing the silicon dots terminally treated and formed thereon was observed with the transmission electron microscope (TEM), and it was confirmed that the silicon dots having uniform particle diameters and exhibiting a uniform distribution and a high density state were formed independently of each other. From the TEM images, the particle diameters of the silicon dots of 50 in number were measured. It was confirmed that the average of the measured values was 16 nm, and it was confirmed that the silicon dots having particle diameters not exceeding 20 nm were substantially formed. The dot density was about 6.1×10¹¹ pcs(pieces)/cm².

In addition, silicon dots were formed as in the Experiment Examples 1 to 4 using the apparatus of the type shown in FIG. 1 except that a nitrogen gas was used instead of an oxygen gas in terminating treatment. The section of the thus obtained substrate bearing the silicon dots terminally treated and formed thereon was observed with the transmission electron microscope (TEM), and observation results respectively similar to those in the Experiment Examples 1 to 4 were obtained.

The silicon dots terminally treated and obtained by the above mentioned experiments were observed to determine a photoluminescence emission and it was confirmed that the dots exhibited high luminance.

### [7] Another Example of Silicon Dot Forming Apparatus

Next, referring to FIG. 6, description will be given on an example of the silicon dot forming apparatus wherein a terminating treatment can be carried out in the silicon dot forming chamber. A silicon dot forming apparatus C shown in FIG. 6 is such that the silicon dot forming chamber 1 in the apparatus A shown in FIG. 1 is used as a terminally treating chamber.

In the apparatus C, the holder 2 is arranged in the chamber 1 via an electrically insulating member 11 and is connected to a switch-over switch SW. One terminal of the switch SW is grounded and the other terminal is connected to the high-frequency power source 40 via a matching box 401. The terminally treating gas can be supplied into the chamber 1 through a nozzle N from the terminally treating gas supply device 9.

The parts and the like in the apparatus C shown in FIG. 6 which are substantially the same as those in the apparatus A shown in FIG. 1 bear the same reference numerals or symbols.

According to the apparatus C, the holder 2 is brought to a grounded state by the operation of the switch SW in the silicon dot forming step prior to terminating treatment, and silicon dots can be formed on the substrate S in the same manner as in the case of the apparatus A. In the terminally treating step, the switch SW operates to link the holder 2 with the power source 40. Then plasma for terminating treatment is formed using a terminally treating gas supply device 9 and the power source 40 so that the silicon dots on the substrate are subjected to terminating treatment.

In the terminally treating step in the apparatus C of FIG. 6, the high-frequency power and the internal chamber pressure are preferably controlled to keep the silicon sputter targets 30 from being sputtered or, even if sputtered, to suppress sputtering to the utmost point.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A silicon dot forming method including:
a step of arranging a silicon sputter target in a silicon dot forming chamber;
a silicon dot forming step of arranging a silicon dot formation target substrate in the silicon dot forming chamber, supplying a sputtering gas into the chamber, applying a high-frequency power to the gas to generate plasma for sputtering in the chamber, and forming silicon dots on the silicon dot formation target substrate by effecting chemical sputtering on the silicon sputter target with the plasma thus formed; and
a terminally treating step of arranging in a terminally treating chamber the substrate bearing the silicon dots formed thereon by the silicon dot forming step, supplying at least one terminally treating gas selected from an oxygen-containing gas and a nitrogen-containing gas into the terminally treating chamber, applying a high-frequency power to the gas(es) to generate plasma for terminating treatment, and terminally treating the silicon dots on the substrate with the terminally treating plasma.

2. The silicon dot forming method according to claim 1, wherein said plasma for sputtering exhibits a ratio (Si(288 nm)/Hβ) of 10.0 or lower between an emission intensity Si(288 nm) of silicon atoms at a wavelength of 288 nm and an emission intensity Hβ of hydrogen atoms at a wavelength of 484 nm in plasma emission.

3. A silicon dot forming method including:
a silicon dot forming step of supplying a silane-containing gas and a hydrogen gas into a silicon dot forming chamber accommodating a silicon dot formation target substrate, applying a high-frequency power to the gases to generate plasma for silicon dot formation exhibiting a ratio (Si(288 nm)/Hβ) of 10.0 or lower between an emission intensity Si(288 nm) of silicon atoms at a wavelength of 288 nm and an emission intensity Hβ of hydrogen atoms at a wavelength of 484 nm in plasma emission in the chamber and thereby forming silicon dots on the substrate with the plasma; and
a terminally treating step of arranging in a terminally treating chamber the substrate bearing the silicon dots formed by the silicon dot forming step, supplying at least one terminally treating gas selected from an oxygen-containing gas and a nitrogen-containing gas into the terminally treating chamber, applying a high-frequency power to the gas(es) to form plasma for terminating treatment, and terminally treating the silicon dots on the substrate with the terminally treating plasma.

4. The silicon dot forming method according to claim 3, wherein
a silicon sputter target is arranged in the silicon dot forming chamber prior to the step of silicon dot formation, and chemical sputtering of the silicon sputter target with the plasma for silicon dot formation is employed in combination in the silicon dot forming step.

5. The silicon dot forming method according to any one of the preceding claims 1 to 4, wherein
the silicon dot forming chamber is allowed to serve as both the silicon dot forming chamber and the terminally treating chamber.

6. The silicon dot forming method according to any one of the preceding claims 1 to 4, wherein
the terminally treating chamber is communicated with the silicon dot forming chamber.

7. A silicon dot forming apparatus including:
a silicon dot forming chamber having a holder for holding a silicon dot formation target substrate;
a hydrogen gas supply device supplying a hydrogen gas into the silicon dot forming chamber;
a silane-containing gas supply device supplying a silane-containing gas into the silicon dot forming chamber;
a first exhaust device exhausting a gas from the silicon dot forming chamber;
a first high-frequency power applying device applying a high-frequency power to the hydrogen gas supplied into the silicon dot forming chamber from the hydrogen gas supply device and the silane-containing gas supplied into the silicon dot forming chamber from the silane-containing gas supply device, and thereby forming plasma for forming a silicon film on an inner wall of the silicon dot forming chamber;
a second high-frequency power applying device applying a high-frequency power to the hydrogen gas supplied into the silicon dot forming chamber from the hydrogen gas supply device after the above silicon film formation, and thereby forming plasma for chemical sputtering on the silicon film as a sputter target;
an optical emission spectroscopic analyzer for plasma obtaining a ratio (Si(288 nm)/Hβ) between an emission intensity Si(288 nm) of silicon atoms at a wavelength of 288 nm and an emission intensity Hβ of hydrogen atoms at a wavelength of 484 nm in plasma emission in the silicon dot forming chamber;
a terminally treating chamber for terminating treatment of silicon dots which chamber has a holder holding a substrate having the silicon dots formed thereon;
a terminally treating gas supply device supplying at least one terminally treating gas selected from an oxygen-containing gas and a nitrogen-containing gas into the terminally treating chamber;
a second exhaust device exhausting a gas from the terminally treating chamber; and
a third high-frequency power applying device applying a high-frequency power to the terminally treating gas supplied into the terminally treating chamber from the terminally treating gas supply device, and thereby forming plasma for terminating treatment.

8. A silicon dot forming apparatus including:
a target forming chamber having a holder for holding a sputter target substrate;
a first hydrogen gas supply device supplying a hydrogen gas into the target forming chamber;
a silane-containing gas supply device supplying a silane-containing gas into the target forming chamber;
a first exhaust device exhausting a gas from the target forming chamber;
a first high-frequency power applying device applying a high-frequency power to the hydrogen gas supplied into the target forming chamber from the first hydrogen gas supply device and the silane-containing gas supplied into the target forming chamber from the silane-containing gas supply device, and thereby forming plasma for forming a silicon film on the sputter target substrate to obtain a silicon sputter target;
a silicon dot forming chamber airtightly communicated with the target forming chamber and having a holder for holding a silicon dot formation target substrate;
a transferring device transferring the silicon sputter target from the target forming chamber to the silicon dot forming chamber without exposing the sputter target to an ambient air;
a second hydrogen gas supply device supplying a hydrogen gas into the silicon dot forming chamber;
a second exhaust device exhausting a gas from the silicon dot forming chamber;
a second high-frequency power applying device applying a high-frequency power to the hydrogen gas supplied from the second hydrogen gas supply device into the silicon dot forming chamber, and thereby forming plasma for effecting chemical sputtering on the silicon sputter target transferred from the target forming chamber;
an optical emission spectroscopic analyzer for plasma obtaining a ratio (Si(288 nm)/Hβ) between an emission intensity Si(288 nm) of silicon atoms at a wavelength of 288 nm and an emission intensity Hβ of hydrogen atoms at a wavelength of 484 nm in emission of the plasma for sputtering in the silicon dot forming chamber;
a terminally treating chamber for terminating treatment of silicon dots which chamber has a holder holding a substrate having the silicon dots formed thereon;
a terminally treating gas supply device supplying at least one terminally treating gas selected from an oxygen-containing gas and a nitrogen-containing gas into the terminally treating chamber;
a third exhaust device exhausting a gas from the terminally treating chamber; and
a third high-frequency power applying device applying a high-frequency power to the terminally treating gas supplied from the terminally treating gas supply device into the terminally treating chamber, and thereby forming plasma for terminating treatment.

9. A silicon dot forming apparatus including:
a silicon dot forming chamber having a holder for holding a silicon dot formation target substrate;
a silicon sputter target arranged in the silicon dot forming chamber;
a hydrogen gas supply device supplying a hydrogen gas into the silicon dot forming chamber;
a first exhaust device exhausting a gas from the silicon dot forming chamber;
a first high-frequency power applying device applying a high-frequency power to the hydrogen gas supplied into the silicon dot forming chamber from the hydrogen gas supply device, and thereby forming plasma for chemical sputtering on the silicon sputter target;
an optical emission spectroscopic analyzer for plasma obtaining a ratio (Si(288 nm)/Hβ) between an emission intensity Si(288 nm) of silicon atoms at a wavelength of 288 nm and an emission intensity Hβ of hydrogen atoms at a wavelength of 484 nm in emission of the plasma for sputtering in the silicon dot forming chamber;
a terminally treating chamber for terminating treatment of silicon dots which chamber has a holder holding a substrate having the silicon dots formed thereon;
a terminally treating gas supply device supplying at least one treating gas selected from an oxygen-containing gas and a nitrogen-containing gas into the terminally treating chamber;
a second exhaust device exhausting a gas from the terminally treating chamber; and
a second high-frequency power applying device applying a high-frequency power to the terminally treating gas supplied into the terminally treating chamber from the terminally treating gas supply device, and thereby forming plasma for terminating treatment.

10. A silicon dot forming apparatus including:
a silicon dot forming chamber having a holder for holding a silicon dot formation target substrate;
a hydrogen gas supply device supplying a hydrogen gas into the silicon dot forming chamber;
a silane-containing gas supply device supplying a silane-containing gas into the silicon dot forming chamber;
a first exhaust device exhausting a gas from the silicon dot forming chamber;
a first high-frequency power applying device applying a high-frequency power to the gases supplied into the silicon dot forming chamber from the hydrogen gas supply device and the silane-containing gas supply device, and thereby forming plasma for silicon dot formation;
an optical emission spectroscopic analyzer for plasma obtaining a ratio (Si(288 nm)/Hβ) between an emission intensity Si(288 nm) of silicon atoms at a wavelength of 288 nm and an emission intensity Hβ of hydrogen atoms at a wavelength of 484 nm in emission of the plasma for silicon dot formation in the silicon dot forming chamber;
a terminally treating chamber for terminating treatment of silicon dots which chamber has a holder holding a substrate having the silicon dots formed thereon;
a terminally treating gas supply device supplying at least one terminally treating gas selected from an oxygen-containing gas and a nitrogen-containing gas into the terminally treating chamber;
a second exhaust device exhausting a gas from the terminally treating chamber; and
a second high-frequency power applying device applying a high-frequency power to the terminally treating gas supplied into the terminally treating chamber from the terminally treating gas supply device, and thereby forming plasma for terminating treatment.

11. The silicon dot forming apparatus according to any one of the preceding claims 7 to 10, wherein the silicon dot forming chamber is used to serve as both the silicon dot forming chamber and the terminally treating chamber.

12. The silicon dot forming apparatus according to any one of the preceding claims 7 to 10, wherein the terminally treating chamber is communicated with the silicon dot forming chamber.
